(19) United States
(12) Patent Application Publication
(10) Pub. No.: US 2025/0207243 A1
(43) Pub. Date: Jun. 26, 2025

(54) DEPOSITION EQUIPMENT

(71) Applicant: Samsung Display Co., LTD., Yongin-si (KR)

(72) Inventor: Sung Woon KIM, Yongin-si (KR)

(73) Assignee: Samsung Display Co., LTD., Yongin-si (KR)

(21) Appl. No.: 18/815,251

(22) Filed: Aug. 26, 2024

(30) Foreign Application Priority Data
Dec. 20, 2023 (KR) 10-2023-0187274

(51) Int. Cl. C23C 16/04; C23C 16/455; G02B 27/01

(52) U.S. Cl. CPC C23C 16/042; C23C 16/45544; G02B 27/0176; G02B 2027/0178

(57) ABSTRACT

A deposition equipment includes a chamber, a deposition source disposed inside the chamber, a mask disposed between a first substrate and the deposition source inside the chamber, and a mask support disposed between the deposition source and the mask and supporting at least a portion of the mask. The mask includes a plurality of cell areas and a mask frame area excluding the plurality of cell areas, the mask frame area includes a mask rib area separating the plurality of cell areas and an outer frame area disposed at an outermost periphery of the mask, the mask support includes a plurality of support ribs, each supporting the mask rib area and having a cross-sectional structure having a taper angle, and the taper angle of each of the plurality of support ribs are different from each other.

### CROSS-REFERENCE TO RELATED APPLICATION(S)

This application claims priority to and benefits of Korean Patent Application No. 10-2023-0187274 under 35 USC § 119, filed on Dec. 20, 2023, in the Korean Intellectual Property Office (KIPO), the entire contents of which are incorporated herein by reference.

### BACKGROUND

### 1. Technical Field

The disclosure relates to deposition equipment.

### 2. Description of the Related Art

A wearable device that forms a focus at a short distance from a user's eyes is being developed in the form of glasses or a helmet. For example, the wearable device may be a head mounted display (HMD) device or augmented reality (AR) glasses. Such a wearable device provides an AR screen or a virtual reality (VR) screen to a user.

A wearable device such as an HMD device or AR glasses is required to have a display specification of at least 2000 pixels per inch (PPI) so that a user can use it for a long time without dizziness. To this end, organic light emitting diode on silicon (OLEDoS) technology, which is a small high-resolution organic light emitting display device, is being proposed. OLEDoS is a technology for placing an organic light emitting diode (OLED) on a semiconductor wafer substrate on which a complementary metal oxide semiconductor (CMOS) is disposed.

In order to manufacture a display panel with a high resolution of 3500 PPI or higher, a high-resolution deposition mask is required.

### SUMMARY

Aspects of the disclosure provide deposition equipment used to readily manufacture a display device with a high resolution of 3500 pixels per inch (PPI) or higher.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment of the disclosure, deposition equipment may include a chamber, a deposition source disposed inside the chamber, a mask disposed between a first substrate and the deposition source inside the chamber, and a mask support disposed between the deposition source and the mask and supporting at least a portion of the mask. The mask may include a plurality of cell areas and a mask frame area excluding the plurality of cell areas, the mask frame area may include a mask rib area separating the plurality of cell areas and an outer frame area disposed at an outermost periphery of the mask, the mask support may include a plurality of support ribs, each supporting the mask rib area and having a cross sectional structure having a taper angle, and the taper angle of each of the plurality of support ribs may be different from each other.

The mask support may further include an electrostatic chuck which supports the outer frame area.

The electrostatic chuck of the mask support may be integrally formed with the plurality of support ribs.

The electrostatic chuck of the mask support may be provided separately from the plurality of support ribs and coupled to some of the plurality of support ribs.

A material of the mask support may include invar.

A material of the mask support may include stainless steel.

The taper angle of each of the plurality of support ribs may be smaller than or equal to a deposition incidence angle formed by the deposition source and each of the plurality of support ribs.

The plurality of support ribs may include a first support rib which forms a first deposition incidence angle with the deposition source and supports a first mask rib area spaced apart from a center of the mask by a first distance, a second support rib which forms a second deposition incidence angle greater than the first deposition incidence angle with the deposition source and supports a second mask rib area spaced apart from the center of the mask by a second distance, and a third support rib which forms a third deposition incidence angle greater than the second deposition incidence angle with the deposition source and supports a third mask rib area spaced apart from the center of the mask by a third distance.

A cross-sectional structure of the first support rib may have a first taper angle smaller than or equal to the first deposition incidence angle, a cross-sectional structure of the second support rib may have a second taper angle smaller than or equal to the second deposition incidence angle, and a cross-sectional structure of the third support rib may have a third taper angle smaller than or equal to the third deposition incidence angle.

The first taper angle may be greater than or equal to the second taper angle, and the second taper angle may be greater than or equal to the third taper angle.

The first taper angle may be smaller than or equal to the second taper angle, and the second taper angle may be smaller than or equal to the third taper angle.

The first taper angle may be equal to the third taper angle, and the second taper angle may be smaller than the first taper angle.

The first taper angle may be equal to the third taper angle and smaller than the second taper angle.

Each of the first through third support ribs may have a symmetrical structure in a cross-sectional view.

Each of the first through third support ribs may have an asymmetrical structure in a cross-sectional view.

Heights of the first through third support ribs may be different from each other.

The first support rib may have a first height, the second support rib may have a second height greater than the first height, and the third support rib may have a third height greater than the second height.

The first support rib may have a first height, the second support rib may have a second height smaller than the first height, and the third support rib may have a third height smaller than the second height.

The mask may further include a mask membrane including an inorganic layer.

The mask may further include a mask membrane including a metal layer.

### BRIEF DESCRIPTION OF THE DRAWINGS

These and/or other aspects will become apparent and more readily appreciated from the following description of the embodiments, taken in conjunction with the accompanying drawings in which:

FIG. 1 is an exploded perspective view of a display device according to an embodiment;

FIG. 2 is a schematic block diagram of the display device according to an embodiment;

FIG. 3 is a schematic diagram of an equivalent circuit of a first subpixel according to an embodiment;

FIG. 4 is a plan view illustrating a layout of a display panel according to an embodiment;

FIG. 5 is a plan view illustrating a layout of a display area of FIG. 4 according to an embodiment;

FIG. 6 is a plan view illustrating a layout of a display area of FIG. 4 according to an embodiment;

FIG. 7 is a schematic cross-sectional view of the display panel, taken along line I1-I1′ of FIG. 5 according to an embodiment;

FIG. 8 is a perspective view of a head mounted display device according to an embodiment;

FIG. 9 is an exploded perspective view of the head mounted display device of FIG. 8 according to an embodiment;

FIG. 10 is a perspective view of a head mounted display device according to an embodiment;

FIG. 11 is a perspective view of a mask according to an embodiment;

FIG. 12 is a schematic plan view of the mask according to the embodiment;

FIG. 13 is a schematic cross-sectional view illustrating the configuration of deposition equipment according to an embodiment;

FIG. 14 is a schematic cross-sectional view of a mask according to an embodiment;

FIG. 15 is a perspective view of a mask support according to an embodiment;

FIG. 16 schematically illustrates multiple support ribs of the mask support according to the embodiment; and

FIGS. 17 through 23 are schematic cross-sectional views illustrating structures of first through third support ribs according to embodiments.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be more thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Features of each of various embodiments of the disclosure may be partially or entirely combined with each other and may technically variously interwork with each other, and respective embodiments may be implemented independently of each other or may be implemented together in association with each other.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described with reference to the accompanying drawings.

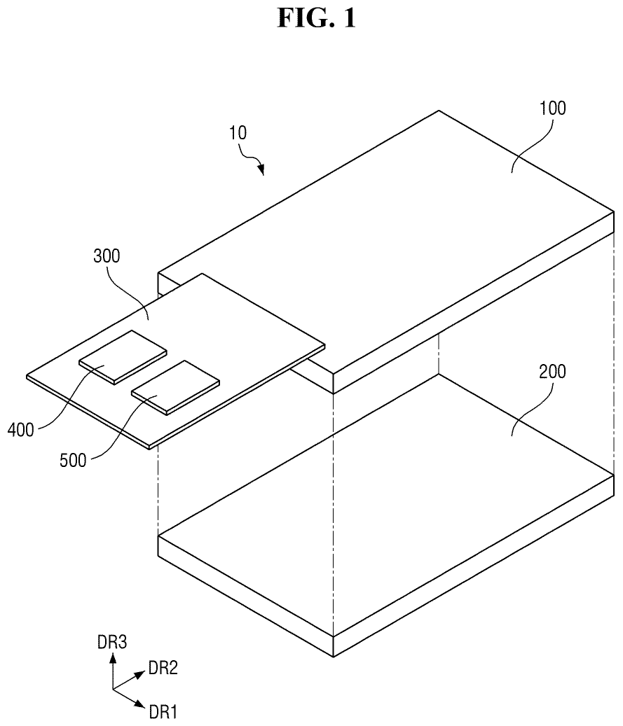

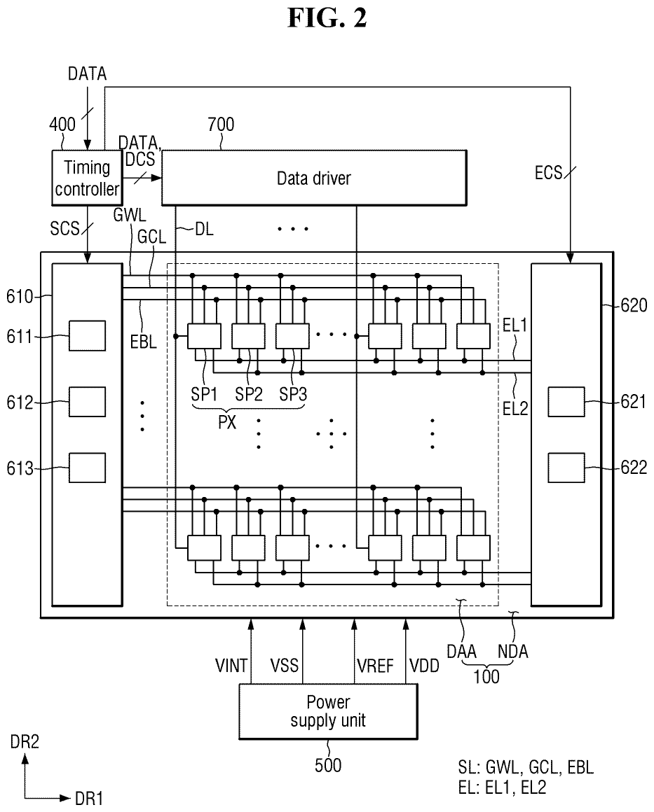

FIG. 1 is an exploded perspective view of a display device 10 according to an embodiment. FIG. 2 is a schematic block diagram of the display device 10 according to an embodiment.

Referring to FIGS. 1 and 2, the display device 10 according to an embodiment may be a device for displaying moving images or still images. The display device 10 according to an embodiment may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 according to an embodiment may be applied as a display unit of a television, a notebook computer, a monitor, a billboard, or an Internet of things (IoT) device. In another embodiment, the display device 10 according to an embodiment may be applied to smart watches, watch phones, and head mounted displays for implementing virtual reality and augmented reality.

The display device 10 according to an embodiment may include a display panel 100, a heat dissipation layer 200, a circuit board 300, a timing controller 400, and a power supply unit 500.

The display panel 100 may have a shape similar to a quadrangle in a plan view. For example, the display panel 100 may have a shape similar to a quadrangle having short sides in a first direction DR1 and long sides in a second direction DR2 intersecting the first direction DR1 in a plan view. In the display panel 100, each corner where a short side extending in the first direction DR1 meets a long side extending in the second direction DR2 may be rounded with a curvature or may be right-angled. The planar shape of the display panel 100 is not limited to a quadrangular shape and may be similar to other polygonal shapes, a circular shape, or an oval shape. The planar shape of the display device 10 may follow the planar shape of the display panel 100, but embodiments of the disclosure are not limited thereto.

As illustrated in FIG. 2, the display panel 100 may include a display area DAA that displays an image and a non-display area NDA that does not display an image.

The display area DAA may include multiple pixels PX, multiple scan lines SL, multiple emission control lines EL, and multiple data lines DL.

The pixels PX may be arranged in a matrix form in the first direction DR1 and the second direction DR2. The scan lines SL and the emission control lines EL may extend in the first direction DR1 and may be arranged in the second direction DR2. The data lines DL may extend in the second direction DR2 and may be arranged in the first direction DR1.

The scan lines SL may include multiple write scan lines GWL, multiple control scan lines GCL, and multiple bias scan lines EBL. The emission control lines EL may include multiple first emission control lines EL1 and multiple second emission control lines EL2.

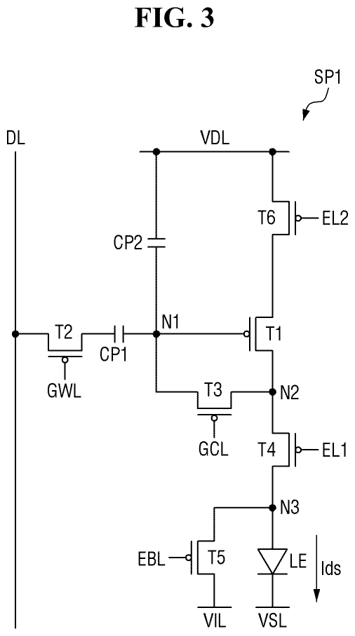

Each of the pixels PX may include multiple subpixels SP1 through SP3. Each of the subpixels SP1 through SP3 may include multiple pixel transistors as illustrated in FIG. 3.

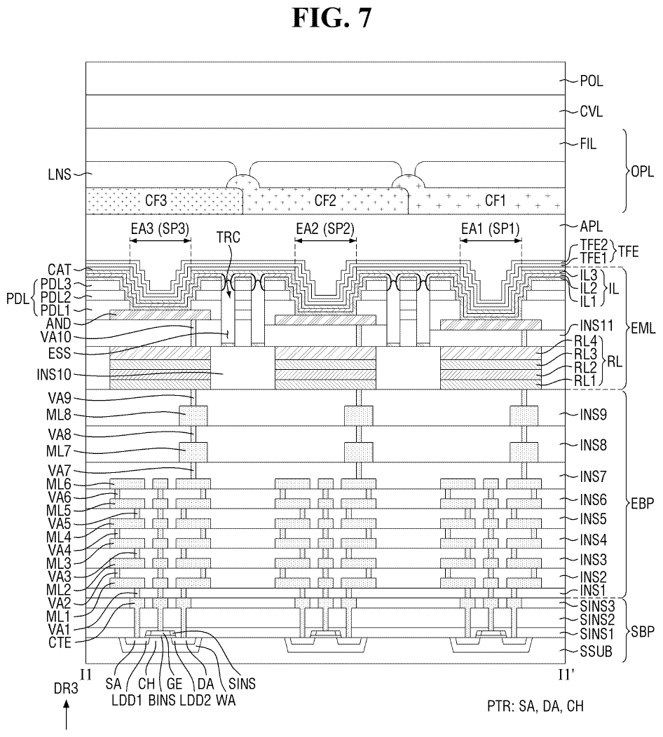

The pixel transistors may be formed through a semiconductor process and may be disposed on a semiconductor substrate SSUB (see FIG. 7). For example, multiple pixel transistors of a data driver 700 may be formed as complementary metal oxide semiconductor (CMOS).

Each of the subpixels SP1 through SP3 may be connected to one of the write scan lines GWL, one of the control scan lines GCL, one of the bias scan lines EBL, one of the first emission control lines EL1, one of the second emission control lines EL2, and one of the data lines DL. Each of the subpixels SP1 through SP3 may receive a data voltage of a data line DL according to a write scan signal of a write scan line GWL and cause a light emitting element to emit light according to the data voltage.

The non-display area NDA may include a scan driver 610, an emission driver 620, and the data driver 700.

The scan driver 610 may include multiple scan transistors, and the emission driver 620 may include multiple emission transistors. The scan transistors and the emission transistors may be formed through a semiconductor process and may be formed on the semiconductor substrate SSUB (see FIG. 7). For example, the scan transistors and the emission transistors may be formed as CMOS. FIG. 2 illustrates that the scan driver 610 is disposed on a left side of the display area DAA, and the emission driver 620 is disposed on a right side of the display area DAA. However, embodiments of the disclosure are not limited thereto. For example, the scan driver 610 and the emission driver 620 may be disposed on both the left and right sides of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines EBL.

The emission driver 620 may include a first emission control driving unit 621 and a second emission control driving unit 622. Each of the first emission control driving unit 621 and the second emission control driving unit 622 may receive an emission timing control signal ECS from the timing controller 400. The first emission control driving unit 621 may generate first emission control signals according to the emission timing control signal ECS and sequentially output the first emission control signals to the first emission control lines EL1. The second emission control driving unit 622 may generate second emission control signals according to the emission timing control signal ECS and sequentially output the second emission control signals to the second emission control lines EL2.

The data driver 700 may include multiple data transistors. The data transistors may be formed through a semiconductor process and may be formed on the semiconductor substrate SSUB (see FIG. 7). For example, the data transistors may be formed as CMOS.

The data driver 700 may receive digital video data DATA and a data timing control signal DCS from the timing controller 400. The data driver 700 may convert the digital video data DATA into analog data voltages according to the data timing control signal DCS and output the analog data voltages to the data lines DL. Subpixels SP1 through SP3 may be selected by a write scan signal of the scan driver 610, and the data voltages may be supplied to the selected subpixels SP1 through SP3.

The heat dissipation layer 200 may overlap the display panel 100 in a third direction DR3 which is a thickness direction of the display panel 100. The heat dissipation layer 200 may be disposed on a surface, e.g., a back surface of the display panel 100. The heat dissipation layer 200 may dissipate heat generated from the display panel 100. The heat dissipation layer 200 may include a metal layer having high thermal conductivity, such as graphite, silver (Ag), copper (Cu), or aluminum (Al).

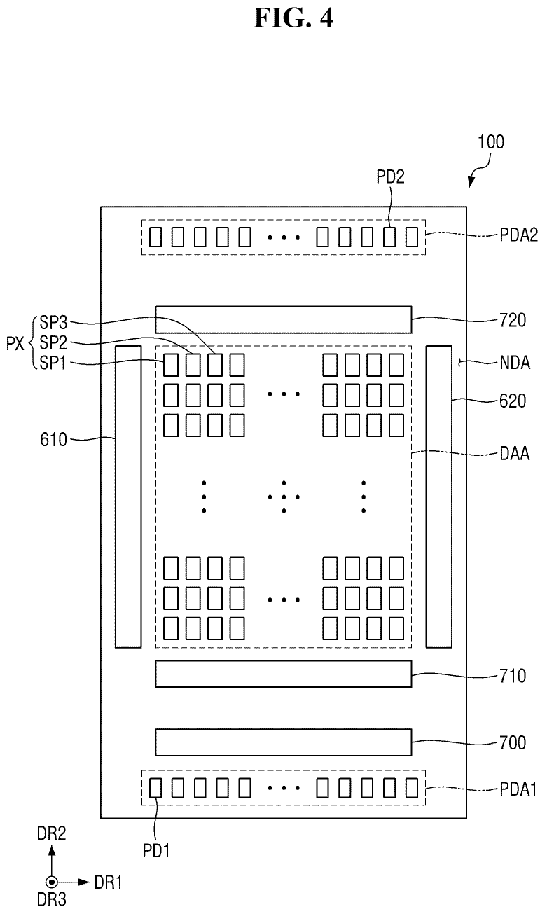

The circuit board 300 may be electrically connected to multiple first pads PD1 (see FIG. 4) in a first pad portion PDA1 (see FIG. 4) of the display panel 100 by using a conductive adhesive member such as an anisotropic conductive film. The circuit board 300 may be a flexible printed circuit board made of a flexible material or may be a flexible film. Although FIG. 1 illustrates that the circuit board 300 is unfolded, the circuit board 300 may be bent, and an end of the circuit board 300 may be placed on the back surface of the display panel 100 and/or a back surface of the heat dissipation layer 200. The end of the circuit board 300 may be an end opposite another end of the circuit board 300 which is connected to the first pads PD1 (see FIG. 4) in the first pad portion PDA1 (see FIG. 4) of the display panel 100 by using the conductive adhesive member.

The timing controller 400 may receive the digital video data DATA and timing signals from the outside. The timing controller 400 may generate the scan timing control signal SCS, the emission timing control signal ECS, and the data timing control signal DCS for controlling the display panel 100 according to the timing signals. The timing controller 400 may output the scan timing control signal SCS to the scan driver 610 and the emission timing control signal ECS to the emission driver 620. The timing controller 400 may output the digital video data DATA and the data timing control signal DCS to the data driver 700.

The power supply unit 500 may generate multiple panel driving voltages according to a power supply voltage received from the outside. For example, the power supply unit 500 may generate a first driving voltage VSS, a second driving voltage VDD, a third driving voltage VINT, and a fourth driving voltage VREF and supply the driving voltages to the display panel 100. The first driving voltage VSS, the second driving voltage VDD, the third driving voltage VINT, and the fourth driving voltage VREF will be described below with reference to FIG. 3.

Each of the timing controller 400 and the power supply unit 500 may be formed as an integrated circuit and attached to a surface of the circuit board 300, and the scan timing control signal SCS, the emission timing control signal ECS, the digital video data DATA, and the data timing control signal DCS of the timing controller 400 may be supplied to the display panel 100 through the circuit board 300. The first driving voltage VSS, the second driving voltage VDD, and the third driving voltage VINT of the power supply unit 500 may be supplied to the display panel 100 through the circuit board 300.

In another embodiment, the timing controller 400 and the power supply unit 500 may be disposed in the non-display area NDA of the display panel 100, like the scan driver 610, the emission driver 620, and the data driver 700, and the timing controller 400 may include multiple timing transistors, and the power supply unit 500 may include multiple power transistors. The timing transistors and the power transistors may be formed through a semiconductor process and may be formed on the semiconductor substrate SSUB (see FIG. 7). For example, the timing transistors and the power transistors may be formed as CMOS. Each of the timing controller 400 and the power supply unit 500 may be disposed between the data driver 700 and the first pad portion PDA1 (see FIG. 4).

FIG. 3 is a schematic diagram of an equivalent circuit of a first subpixel SP1 according to an embodiment.

Referring to FIG. 3, the first subpixel SP1 may be connected to a write scan line GWL, a control scan line GCL, a bias scan line EBL, a first emission control line EL1, a second emission control line EL2, and a data line DL. The first subpixel SP1 may be also connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low-potential voltage line, the second driving voltage line VDL may be a high-potential voltage line, and the third driving voltage line VIL may be an initialization voltage line. The first driving voltage VSS may be lower than the third driving voltage VINT. The second driving voltage VDD may be higher than the third driving voltage VINT.

The first subpixel SP1 may include multiple transistors T1 through T6, a light emitting element LE, a first capacitor CP1, and a second capacitor CP2.

The light emitting element LE may emit light according to a driving current Ids flowing through a channel of a first transistor T1. The amount of light emitted from the light emitting element LE may be proportional to the driving current Ids. The light emitting element LE may be disposed between a fourth transistor T4 and the first driving voltage line VSL. A first electrode of the light emitting element LE may be connected to a drain electrode of the fourth transistor T4, and a second electrode of the light emitting element LE may be connected to the first driving voltage line VSL. The first electrode of the light emitting element LE may be an anode, and the second electrode of the light emitting element LE may be a cathode. The light emitting element LE may be an organic light emitting diode including a first electrode, a second electrode, and an organic light emitting layer disposed between the first electrode and the second electrode. However, embodiments of the disclosure are not limited thereto. For example, the light emitting element LE may be an inorganic light emitting element including a first electrode, a second electrode, and an inorganic semiconductor disposed between the first electrode and the second electrode. The light emitting element LE may be a micro light emitting diode.

The first transistor T1 may be a driving transistor that controls a source-drain current Ids (hereinafter, referred to as a “driving current”) flowing between a source electrode and a drain electrode according to a voltage applied to a gate electrode. The first transistor T1 may include the gate electrode connected to a first node N1, the source electrode connected to a drain electrode of a sixth transistor T6, and the drain electrode connected to a second node N2.

A second transistor T2 may be disposed between an electrode of the first capacitor CP1 and the data line DL. The second transistor T2 may be turned on by a write scan signal of the write scan line GWL and connect the electrode of the first capacitor CP1 to the data line DL. Accordingly, a data voltage of the data line DL may be applied to the electrode of the first capacitor CP1. The second transistor T2 may include a gate electrode connected to the write scan line GWL, a source electrode connected to the data line DL, and a drain electrode connected to the electrode of the first capacitor CP1.

A third transistor T3 may be disposed between the first node N1 and the second node N2. The third transistor T3 may be turned on by a write control signal of the write control line GCL and connect the first node N1 to the second node N2. Accordingly, since the gate electrode and source electrode of the first transistor T1 are connected, the first transistor T1 may operate as a diode. The third transistor T3 may include a gate electrode connected to the write control line GCL, a source electrode connected to the second node N2, and a drain electrode connected to the first node N1.

The fourth transistor T4 may be connected between the second node N2 and a third node N3. The fourth transistor T4 may be turned on by a first emission control signal of the first emission control line EL1 and connect the second node N2 to the third node N3. Accordingly, the driving current of the first transistor T1 may be supplied to the light emitting element LE. The fourth transistor T4 may include a gate electrode connected to the first emission control line EL1, a source electrode connected to the second node N2, and the drain electrode connected to the third node N3.

A fifth transistor T5 may be disposed between the third node N3 and the third driving voltage line VIL. The fifth transistor T5 may be turned on by a bias scan signal of the bias scan line EBL and connect the third node N3 to the third driving voltage line VIL. Accordingly, the third driving voltage VINT of the third driving voltage line VIL may be applied to the first electrode of the light emitting element LE. The fifth transistor T5 may include a gate electrode connected to the bias scan line EBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by a second emission control signal of the second emission control line EL2 and connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and the drain electrode connected to the source electrode of the first transistor T1.

The first capacitor CP1 may be formed between the first node N1 and the drain electrode of the second transistor T2. The first capacitor CP1 may include an electrode connected to the drain electrode of the second transistor T2 and another electrode connected to the first node N1.

The second capacitor CP2 may be formed between the gate electrode of the first transistor T1 and the second driving voltage line VDL. The second capacitor CP2 may include an electrode connected to the gate electrode of the first transistor T1 and another electrode connected to the second driving voltage line VDL.

The first node N1 may be a contact point between the gate electrode of the first transistor T1, the drain electrode of the third transistor T3, the another electrode of the first capacitor CP1, and the electrode of the second capacitor CP2. The second node N2 may be a contact point between the drain electrode of the first transistor T1, the source electrode of the third transistor T3, and the source electrode of the fourth transistor T4. The third node N3 may be a contact point between the drain electrode of the fourth transistor T4, the source electrode of the fifth transistor T5, and the first electrode of the light emitting element LE.

Each of the first through sixth transistors T1 through T6 may be a metal-oxide-semiconductor field effect transistor (MOSFET). For example, each of the first through sixth transistors T1 through T6 may be a P-type MOSFET. However, embodiments of the disclosure are not limited thereto. Each of the first through sixth transistors T1 through T6 may also be an N-type MOSFET. In another embodiment, some of the first through sixth transistors T1 through T6 may be P-type MOSFETs, and other transistors may be N-type MOSFETs.

FIG. 3 illustrates that the first subpixel SP1 includes six transistors T1 through T6 and two capacitors CP1 and CP2. However, it should be noted that the equivalent circuit diagram of the first subpixel SP1 is not limited to that illustrated in FIG. 3. For example, the number of transistors and capacitors of the first subpixel SP1 is not limited to the embodiment illustrated in FIG. 3.

An equivalent circuit diagram of a second subpixel SP2 and an equivalent circuit diagram of a third subpixel SP3 may be substantially the same as the equivalent circuit diagram of the first subpixel SP1 described with reference to FIG. 3. Therefore, the equivalent circuit diagram of the second subpixel SP2 and the equivalent circuit diagram of the third subpixel SP3 will not be described in the specification.

FIG. 4 is a plan view illustrating a layout of a display panel 100 according to an embodiment.

Referring to FIG. 4, a display area DAA of the display panel 100 according to an embodiment may include multiple pixels PX arranged in a matrix form. A non-display area NDA of the display panel 100 according to an embodiment may include a scan driver 610, an emission driver 620, a data driver 700, a first distribution circuit 710, a second distribution circuit 720, a first pad portion PDA1, and a second pad portion PDA2.

The scan driver 610 may be disposed on a first side of the display area DAA, and the emission driver 620 may be disposed on a second side of the display area DAA. For example, the scan driver 610 may be disposed on a side of the display area DAA in the first direction DR1, and the emission driver 620 may be disposed on another side of the display area DAA in the first direction DR1. For example, the scan driver 610 may be disposed on a left side of the display area DAA, and the emission driver 620 may be disposed on a right side of the display area DAA. However, embodiments of the disclosure are not limited thereto, and the scan driver 610 and the emission driver 620 may be disposed on both the first and second sides of the display area DAA.

The first pad portion PDA1 may include multiple first pads PD1 connected to pads or bumps of the circuit board 300 through a conductive adhesive member. The first pad portion PDA1 may be disposed on a third side of the display area DAA. For example, the first pad portion PDA1 may be disposed on a side of the display area DAA in the second direction DR2.

The first pad portion PDA1 may be disposed on a side of the data driver 700 in the second direction DR2. For example, the first pad portion PDA1 may be disposed closer to an edge of the display panel 100 than the data driver 700.

The second pad portion PDA2 may include multiple second pads PD2 corresponding to test pads for testing whether the display panel 100 operates normally. The second pads PD2 may be connected to a jig or probe pin during a test process or may be connected to a test circuit board. The test circuit board may be a printed circuit board made of a rigid material or a flexible printed circuit board made of a flexible material.

The first distribution circuit 710 may distribute data voltages received through the first pad portion PDA1 to multiple data lines DL. For example, the first distribution circuit 710 may distribute data voltages received through one first pad PD1 of the first pad portion PDA1 to P (P is a positive integer greater than or equal to 2) data lines DL. Therefore, the number of first pads PD1 may be reduced. The first distribution circuit 710 may be disposed on the third side of the display area DAA of the display panel 100. For example, the first distribution circuit 710 may be disposed on a side of the display area DAA in the second direction DR2. For example, the first distribution circuit 710 may be disposed on the lower side of the display area DAA.

The second distribution circuit 720 may distribute signals received through the second pad portion PDA2 to the scan driver 610, the emission driver 620, and the data lines DL. The second pad portion PDA2 and the second distribution circuit 720 may be elements for testing the operation of each of the pixels PX in the display area DAA. The second distribution circuit 720 may be disposed on a fourth side of the display area DAA of the display panel 100. For example, the second distribution circuit 720 may be disposed on another side of the display area DAA in the second direction DR2. For example, the second distribution circuit 720 may be disposed on an upper side of the display area DAA.

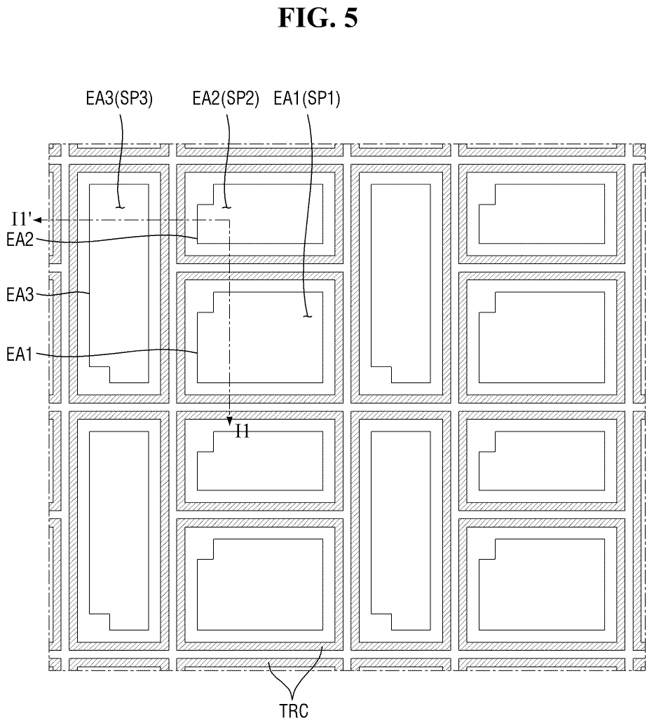

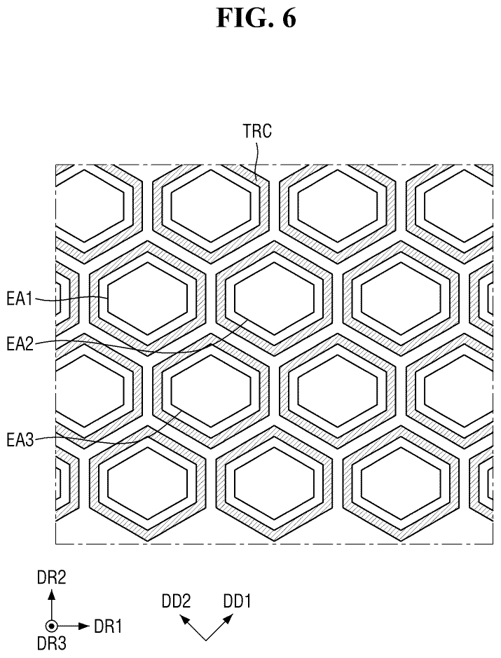

FIGS. 5 and 6 are plan views illustrating a layout of the display area DAA of FIG. 4 according to embodiments.

Referring to FIGS. 5 and 6, each of the pixels PX may have a first emission area EA1 which is an emission area of a first subpixel SP1, a second emission area EA2 which is an emission area of a second subpixel SP2, and a third emission area EA3 which is an emission area of a third subpixel SP3.

Each of the first emission area EA1, the second emission area EA2, and the third emission area EA3 may have a polygonal, circular, oval, or irregular shape in a plan view.

A maximum length of the third emission area EA2 in the first direction DR1 may be smaller than a maximum length of the first emission area EA1 in the first direction DR1 and a maximum length of the second emission area EA2 in the first direction DR1. The maximum length of the first emission area EA1 in the first direction DR1 and the maximum length of the second emission area EA2 in the first direction DR1 may be substantially the same.

A maximum length of the third emission area EA3 in the second direction DR2 may be greater than a maximum length of the first emission area EA1 in the second direction DR2 and a maximum length of the second emission area EA2 in the second direction DR2. The maximum length of the first emission area EA1 in the second direction DR2 may be greater than the maximum length of the second emission area EA2 in the second direction DR2.

The first emission area EA1, the second emission area EA2, and the third emission area EA3 may have a hexagonal shape in a plan view composed of six straight lines as illustrated in FIGS. 5 and 6. However, embodiments of the disclosure are not limited thereto. The first emission area EA1, the second emission area EA2, and the third emission area EA3 may have a polygonal planar shape other than a hexagonal shape or a circular, oval or irregular planar shape.

As illustrated in FIG. 5, in each of the pixels PX, the first emission area EA1 and the second emission area EA2 may be adjacent to each other in the first direction DR1. The first emission area EA1 and the third emission area EA3 may be adjacent to each other in the first direction DR1. The second emission area EA2 and the third emission area EA3 may be adjacent to each other in the second direction DR2. The area of the first emission area EA1, the area of the second emission area EA2, and the area of the third emission area EA3 may be different in a plan view.

In another embodiment, as illustrated in FIG. 6, the first emission area EA1 and the second emission area EA2 may be adjacent to each other in the first direction DR1. However, the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2 and a direction inclined by 45 degrees with respect to the first direction DR1 and the second direction DR2. The second diagonal direction DD2 may be a direction orthogonal to the first diagonal direction DD1.

The first emission area EA1 may emit light of a first color, the second emission area EA2 may emit light of a second color, and the third emission area EA3 may emit light of a third color. In an embodiment, the light of the first color may be light in a blue wavelength band, the light of the second color may be light in a green wavelength band, and the light of the third color may be light in a red wavelength band. For example, the blue wavelength band may have a main peak wavelength of light included in a wavelength band in a range of about 370 nm to about 460 nm, the green wavelength band may have a main peak wavelength of light included in a wavelength band in a range of about 480 nm to about 560 nm, and the red wavelength band may have a main peak wavelength of light included in a wavelength band in a range of about 600 nm to about 750 nm.

Although each of the pixels PX includes three emission areas EA1 through EA3 in FIGS. 5 and 6, embodiments of the disclosure are not limited thereto. In another embodiment, each of the pixels PX may include four emission areas.

The arrangement of the emission areas of the pixels PX is not limited to those illustrated in FIGS. 5 and 6. For example, the emission areas of the pixels PX may be arranged in a stripe structure in which emission areas are arranged in the first direction DR1, in a PenTile® structure in which emission areas are arranged in a diamond shape, or in a hexagonal structure in which emission areas having a hexagonal planar shape are arranged as illustrated in FIG. 6.

FIG. 7 is a schematic cross-sectional view of the display panel 100, taken along line I1-I1′ of FIG. 5 according to an embodiment.

Referring to FIG. 7, the display panel 100 may include a semiconductor backplane SBP, a light emitting element backplane EBP, a display element layer EML, an encapsulation layer TFE, an optical layer OPL, a cover layer CVL, and a polarizer POL.

The semiconductor backplane SBP may include a semiconductor substrate SSUB including multiple pixel transistors PTR, multiple semiconductor insulating layers covering the pixel transistors PTR, and multiple contact terminals CTE electrically connected to the pixel transistors PTR. The pixel transistors PTR may be the first through sixth transistors T1 through T6 described with reference to FIG. 3.

The semiconductor substrate SSUB may be a silicon substrate, a germanium substrate, or a silicon-germanium substrate. The semiconductor substrate SSUB may be a substrate doped with first-type impurities. Multiple well areas WA may be formed on an upper surface of the semiconductor substrate SSUB. The well areas WA may be areas doped with second-type impurities. The second-type impurities may be different from the first-type impurities described above. For example, in case that the first-type impurities are p-type impurities, the second-type impurities may be n-type impurities. In another embodiment, in case that the first-type impurities are n-type impurities, the second-type impurities may be p-type impurities.

Each of the well areas WA may include a source area SA corresponding to a source electrode of a pixel transistor PTR, a drain area DA corresponding to a drain electrode of the pixel transistor PTR, and a channel area CH disposed between the source area SA and the drain area DA.

A bottom insulating layer BINS may be disposed between a gate electrode GE and each well area WA. A side insulating layer SINS may be disposed on side surfaces of the gate electrode GE.

Each of the source area SA and the drain area DA may be an area doped with the first-type impurities. The gate electrode GE of each pixel transistor PTR may overlap a well area WA in the third direction DR3. The channel area CH may overlap the gate electrode GE in the third direction DR3. The source area SA may be disposed on a side of the gate electrode GE, and the drain area DA may be disposed on another side of the gate electrode GE.

Each of the well areas WA may further include a first lightly doped impurity area LDD1 disposed between the channel area CH and the source area SA and a second lightly doped impurity area LDD2 disposed between the channel area CH and the drain area DA. The first lightly doped impurity area LDD1 may be an area having a lower impurity concentration than the source area SA due to the bottom insulating layer BINS. The second lightly doped impurity area LDD2 may be an area having a lower impurity concentration than the drain area DA due to the bottom insulating layer BINS. A distance between the source area SA and the drain area DA may be increased by the first lightly doped impurity area LDD1 and the second lightly doped impurity area LDD2. Accordingly, a length of the channel area CH of each pixel transistor PTR may increase, thereby preventing punch-through and hot carrier phenomena caused by a short channel.

A first semiconductor insulating layer SINS1 may be disposed on the semiconductor substrate SSUB. The first semiconductor insulating layer SINS1 may be a silicon carbon nitride (SiCN) or silicon oxide (SiOₓ)-based inorganic layer, but embodiments of the disclosure are not limited thereto.

A second semiconductor insulating layer SINS2 may be disposed on the first semiconductor insulating layer SINS1. The second semiconductor insulating layer SINS2 may be a silicon oxide (SiOₓ)-based inorganic layer, but embodiments of the disclosure are not limited thereto.

The contact terminals CTE may be disposed on the second semiconductor insulating layer SINS2. Each of the contact terminals CTE may be connected to one of the gate electrode GE, the source area SA, and the drain area DA of a pixel transistor PTR through a hole penetrating the first semiconductor insulating layer SINS1 and the second semiconductor insulating layer SINS2. The contact terminals CTE may be made of at least one of copper (Cu), aluminum (Al), tungsten (W), molybdenum (Mo), chromium (Cr), gold (Au), titanium (Ti), nickel (Ni), neodymium (Nd), and an alloy thereof.

A third semiconductor insulating layer SINS3 may be disposed on side surfaces of each of the contact terminals CTE. An upper surface of each of the contact terminals CTE may be exposed without being covered by the third semiconductor insulating layer SINS3. The third semiconductor insulating layer SINS3 may be a silicon oxide (SiOx)-based inorganic layer, but embodiments of the disclosure are not limited thereto.

The semiconductor substrate SSUB may be replaced with a glass substrate or a polymer resin substrate such as polyimide, and thin-film transistors may be disposed on the glass substrate or the polymer resin substrate. The glass substrate may be a rigid substrate that is not bendable, and the polymer resin substrate may be a flexible substrate that can be bent or curved.

The light emitting element backplane EBP may include multiple conductive layers ML1 through ML8, multiple vias VA1 through VA9, and multiple insulating layers INS1 through INS9. The light emitting element backplane EBP may also include multiple insulating layers INS1 through INS9 disposed between first through eighth conductive layers ML1 through ML8.

The first through eighth conductive layers ML1 through ML8 may implement the circuit of the first subpixel SP1 illustrated in FIG. 3 by connecting the contact terminals CTE exposed in the semiconductor backplane SBP. For example, only the first through sixth transistors T1 through T6 may be formed in the semiconductor backplane SBP, and the connection of the first through sixth transistors T1 through T6 and the first and second capacitors C1 and C2 may be achieved through the first through eighth conductive layers ML1 through ML8. The connection between a drain area corresponding to the drain electrode of the fourth transistor T4, a source area corresponding to the source electrode of the fifth transistor T5, and the first electrode of the light emitting element LE may be achieved through the first through eighth conductive layers ML1 through ML8.

A first insulating layer INS1 may be disposed on the semiconductor backplane SBP. First vias VA1 may penetrate the first insulating layer INS1 and may be respectively connected to the contact terminals CTE exposed in the semiconductor backplane SBP. The first conductive layers ML1 may be disposed on the first insulating layer INS1 and may be connected to the first vias VA1, respectively.

A second insulating layer INS2 may be disposed on the first insulating layer INS1 and the first conductive layers ML1. Second vias VA2 may penetrate the second insulating layer INS2 and may be connected to the exposed first conductive layers ML1, respectively. The second conductive layers ML2 may be disposed on the second insulating layer INS2 and may be connected to the second vias VA2, respectively.

A third insulating layer INS3 may be disposed on the second insulating layer INS2 and the second conductive layers ML2. Third vias VA3 may penetrate the third insulating layer INS3 and may be connected to the exposed second conductive layers ML2, respectively. The third conductive layers ML3 may be disposed on the third insulating layer INS3 and may be connected to the third vias VA3, respectively.

A fourth insulating layer INS4 may be disposed on the third insulating layer INS3 and the third conductive layers ML3. Fourth vias VA4 may penetrate the fourth insulating layer INS4 and may be connected to the exposed third conductive layers ML3, respectively. The fourth conductive layers ML4 may be disposed on the fourth insulating layer INS4 and may be connected to the fourth vias VA4, respectively.

A fifth insulating layer INS5 may be disposed on the fourth insulating layer INS4 and the fourth conductive layers ML4. Fifth vias VA5 may penetrate the fifth insulating layer INS5 and may be connected to the exposed fourth conductive layers ML4, respectively. The fifth conductive layers ML5 may be disposed on the fifth insulating layer INS5 and may be connected to the fifth vias VA5, respectively.

A sixth insulating layer INS6 may be disposed on the fifth insulating layer INS5 and the fifth conductive layers ML5. Sixth vias VA6 may penetrate the sixth insulating layer INS6 and may be connected to the exposed fifth conductive layers ML5, respectively. The sixth conductive layers ML6 may be disposed on the sixth insulating layer INS6 and may be connected to the sixth vias VA6, respectively.

A seventh insulating layer INS7 may be disposed on the sixth insulating layer INS6 and the sixth conductive layers ML6. Seventh vias VA7 may penetrate the seventh insulating layer INS7 and may be connected to the exposed sixth conductive layers ML6, respectively. The seventh conductive layers ML7 may be disposed on the seventh insulating layer INS7 and may be connected to the seventh vias VA7, respectively.

An eighth insulating layer INS8 may be disposed on the seventh insulating layer INS7 and the seventh conductive layers ML7. Eighth vias VA8 may penetrate the eighth insulating layer INS8 and may be connected to the exposed seventh conductive layers ML7, respectively. The eighth conductive layers ML8 may be disposed on the eighth insulating layer INS8 and may be connected to the eighth vias VA8, respectively.

The first through eighth conductive layers ML1 through ML8 and the first through eighth vias VA1 through VA8 may be made of substantially the same material. For example, the first through eighth conductive layers ML1 through ML8 and the first through eighth vias VA1 through VA8 may be made of at least one of copper (Cu), aluminum (Al), tungsten (W), molybdenum (Mo), chromium (Cr), gold (Au), titanium (Ti), nickel (Ni), neodymium (Nd), and an alloy thereof. The first through eighth vias VA1 through VA8 may be made of substantially the same material. Each of the first through eighth insulating layers INS1 through INS8 may be a silicon oxide (SiOₓ)-based inorganic layer, but embodiments of the disclosure are not limited thereto.

A thickness of the first conductive layers ML1, a thickness of the second conductive layers ML2, a thickness of the third conductive layers ML3, a thickness of the fourth conductive layers ML4, a thickness of the fifth conductive layers ML5, and a thickness of the sixth conductive layers ML6 may each be greater than a thickness of the first vias VA1, a thickness of the second vias VA2, a thickness of the third vias VA3, a thickness of the fourth vias VA4, a thickness of the fifth vias VA5, and a thickness of the sixth vias VA6 in the third direction DR3. The thickness of the second conductive layers ML2, the thickness of the third conductive layers ML3, the thickness of the fourth conductive layers ML4, the thickness of the fifth conductive layers ML5, and the thickness of the sixth conductive layers ML6 may each be greater than the thickness of the first conductive layers ML1 in the third direction DR3. The thickness of the second conductive layers ML2, the thickness of the third conductive layers ML3, the thickness of the fourth conductive layers ML4, the thickness of the fifth conductive layers ML5, and the thickness of the sixth conductive layers ML6 may be substantially the same. For example, the thickness of the first conductive layers ML1 may be about 1360 Å, and the thickness of the second conductive layers ML2, the thickness of the third conductive layers ML3, the thickness of the fourth conductive layers ML4, the thickness of the fifth conductive layers ML5, and the thickness of the sixth conductive layers ML6 may each be about 1440 Å. The thickness of the first vias VA1, the thickness of the second vias VA2, the thickness of the third vias VA3, the thickness of the fourth vias VA4, the thickness of the fifth vias VA5, and the thickness of the sixth vias VA6 may each be about 1150 Å.

A thickness of the seventh conductive layers ML7 and a thickness of the eighth conductive layers ML8 may each be greater than the thickness of the first conductive layers ML1, the thickness of the second conductive layers ML2, the thickness of the third conductive layers ML3, the thickness of the fourth conductive layers ML4, the thickness of the fifth conductive layers ML5, and the thickness of the sixth conductive layer ML6 in the third direction DR3. The thickness of the seventh conductive layers ML7 and the thickness of the eighth conductive layers ML8 may each be greater than a thickness of the seventh vias VA7 and a thickness of the eighth vias VA8 in the third direction DR3. The thickness of the seventh vias VA7 and the thickness of the eighth vias VA8 may each be greater than the thickness of the first vias VA1, the thickness of the second vias VA2, the thickness of the third vias VA3, the thickness of the fourth vias VA4, the thickness of the fifth vias VA5, and the thickness of the sixth vias VA6. The thickness of the seventh conductive layers ML7 and the thickness of the eighth conductive layers ML8 may be substantially the same. For example, the thickness of the seventh conductive layers ML7 and the thickness of the eighth conductive layers ML8 may each be about 9000 Å. The thickness of the seventh vias VA7 and the thickness of the eighths via VA8 may each be about 6000 Å.

A ninth insulating layer INS9 may be disposed on the eighth insulating layer INS8 and the eighth conductive layers ML8. The ninth insulating layer INS9 may be a silicon oxide (SiOₓ)-based inorganic layer, but embodiments of the disclosure are not limited thereto.

Ninth vias VA9 may penetrate the ninth insulating layer INS9 and may be connected to the exposed eighth conductive layers ML8, respectively. The ninth vias VA9 may be made of at least one of copper (Cu), aluminum (Al), tungsten (W), molybdenum (Mo), chromium (Cr), gold (Au), titanium (Ti), nickel (Ni), neodymium (Nd), and an alloy thereof. A thickness of the ninth vias VA9 may be about 16500 Å in the third direction DR3.

The display element layer EML may be disposed on the light emitting element backplane EBP. The display element layer EML may include a reflective electrode layer RL, tenth and eleventh insulating layers INS10 and INS11, tenth vias VA10, light emitting elements LE, each including a first electrode AND, a light emitting stack IL and a second electrode CAT, a pixel defining layer PDL, and multiple trenches TRC.

The reflective electrode layer RL may be disposed on the ninth insulating layer INS9. The reflective electrode layer RL may include one or more reflective electrodes RL1 through RL4. For example, the reflective electrode layer RL may include first through fourth reflective electrodes RL1 through RL4 as illustrated in FIG. 7.

The first reflective electrodes RL1 may be disposed on the ninth insulating layer INS9 and may be connected to the ninth vias VA9, respectively. The first reflective electrodes RL1 may be made of at least one of copper (Cu), aluminum (Al), tungsten (W), molybdenum (Mo), chromium (Cr), gold (Au), titanium (Ti), nickel (Ni), neodymium (Nd), and an alloy thereof. For example, the first reflective electrodes RL1 may include titanium nitride (TiN).

The second reflective electrodes RL2 may be disposed on the first reflective electrodes RL1, respectively. The second reflective electrodes RL2 may be made of at least one of copper (Cu), aluminum (Al), tungsten (W), molybdenum (Mo), chromium (Cr), gold (Au), titanium (Ti), nickel (Ni), neodymium (Nd), and an alloy thereof. For example, the second reflective electrodes RL2 may include aluminum (Al).

The third reflective electrodes RL3 may be disposed on the second reflective electrodes RL2, respectively. The third reflective electrodes RL3 may be made of at least one of copper (Cu), aluminum (Al), tungsten (W), molybdenum (Mo), chromium (Cr), gold (Au), titanium (Ti), nickel (Ni), neodymium (Nd), and an alloy thereof. For example, the third reflective electrodes RL3 may include titanium nitride (TiN).

The fourth reflective electrodes RL4 may be disposed on the third reflective electrodes RL3, respectively. The fourth reflective electrodes RL4 may be made of at least one of copper (Cu), aluminum (Al), tungsten (W), molybdenum (Mo), chromium (Cr), gold (Au), titanium (Ti), nickel (Ni), neodymium (Nd), and an alloy thereof. For example, the fourth reflective electrodes RL4 may include titanium (Ti).

Since the second reflective electrodes RL2 are electrodes that substantially reflect light from the light emitting elements LE, a thickness of the second reflective electrodes RL2 may be greater than a thickness of the first reflective electrodes RL1, a thickness of the third reflective electrodes RL3, and a thickness of the fourth reflective electrodes RL4 in the third direction DR3. For example, the thickness of the first reflective electrodes RL1, the thickness of the third reflective electrodes RL3 and the thickness of the fourth reflective electrodes RL4 may be about 100 Å, and the thickness of the second reflective electrodes RL2 may be about 850 Å.

The tenth insulating layer INS10 may be disposed on the ninth insulating layer INS9. The tenth insulating layer INS10 may be disposed between reflective electrode layers RL adjacent to each other in a horizontal direction. The tenth insulating layer INS10 may be a silicon oxide (SiOₓ)-based inorganic layer, but embodiments of the disclosure are not limited thereto.

The eleventh insulating layer INS11 may be disposed on the tenth insulating layer INS10 and the reflective electrode layer RL. The eleventh insulating layer INS11 may be a silicon oxide (SiOₓ)-based inorganic layer, but embodiments of the disclosure are not limited thereto. The tenth insulating layer INS10 and the eleventh insulating layer INS11 may be optical auxiliary layers through which light reflected by the reflective electrode layer RL among light emitted from the light emitting elements LE passes.

The tenth insulating layer INS10 or the eleventh insulating layer INS11 may not be disposed under the first electrode AND of at least any one of the first subpixel SP1, a second subpixel SP2, and the third subpixel SP3 in order to match a resonance distance of light emitted from the light emitting elements LE. For example, the first electrode AND of the first subpixel SP1 may be disposed on (e.g., directly disposed on) the reflective electrode layer RL. The eleventh insulating layer INS11 may be disposed under the first electrode AND of the second subpixel SP2. The tenth insulating layer INS10 and the eleventh insulating layer INS11 may be disposed under the first electrode AND of the third subpixel SP3.

In an embodiment, a distance between the first electrode AND and the reflective electrode layer RL may be different in each of the first subpixel SP1, the second subpixel SP2, and the third subpixel SP3. For example, the presence or absence of the tenth insulating layer INS10 and the eleventh insulating layer INS11 in each of the first subpixel SP1, the second subpixel SP2, and the third subpixel SP3 may be set in order to adjust a distance from the reflective electrode layer RL to the first electrode AND according to the main wavelength of light emitted from each of the first subpixel SP1, the second subpixel SP2, and the third subpixel SP3. For example, a distance between the first electrode AND and the reflective electrode layer RL in the third subpixel SP3 may be greater than a distance between the first electrode AND and the reflective electrode layer RL in the second subpixel SP2 and a distance between the first electrode AND and the reflective electrode layer RL in the first subpixel SP1, and the distance between the first electrode AND and the reflective electrode layer RL in the second subpixel SP2 may be greater than the distance between the first electrode AND and the reflective electrode layer RL in the first subpixel SPL. However, embodiments of the disclosure are not limited thereto.

Although the tenth insulating layer INS10 and the eleventh insulating layer INS11 are described in embodiments of the disclosure, a twelfth insulating layer disposed under the first electrode AND of the first subpixel SP1 may also be added. The eleventh insulating layer INS11 and the twelfth insulating layer may be disposed under the first electrode AND of the second subpixel SP2, and the tenth insulating layer INS10, the eleventh insulating layer INS11 and the twelfth insulating layer may be disposed under the first electrode AND of the third subpixel SP3.

The tenth vias VA10 may penetrate the tenth insulating layer INS10 and/or the eleventh insulating layer INS11 in the second subpixel SP2 and the third subpixel SP3 and may be connected to the exposed fourth reflective electrodes RL4, respectively. The tenth vias VA10 may be made of at least one of copper (Cu), aluminum (Al), tungsten (W), molybdenum (Mo), chromium (Cr), gold (Au), titanium (Ti), nickel (Ni), neodymium (Nd), and an alloy thereof. A thickness of a tenth via VA10 in the second subpixel SP2 may be smaller than a thickness of a tenth via VA10 in the third subpixel SP3 in the third direction DR3.

The first electrodes AND of the light emitting elements LE may be disposed on the tenth insulating layer INS10 and may be connected to the tenth vias VA10, respectively. The first electrode AND of each of the light emitting elements LE may be connected to the drain area DA or the source area SA of a pixel transistor PTR through a tenth via VA10, the first through fourth reflective electrodes RL1 through RL4, the first through ninth vias VA1 through VA9, the first through eighth conductive layers ML1 through ML8, and a contact terminal CTE. The first electrode AND of each of the light emitting elements LE may be made of at least one of copper (Cu), aluminum (Al), tungsten (W), molybdenum (Mo), chromium (Cr), gold (Au), titanium (Ti), nickel (Ni), neodymium (Nd), and an alloy thereof. For example, the first electrode AND of each of the light emitting elements LE may include titanium nitride (TiN).

The pixel defining layer PDL may be disposed on a portion of the first electrode AND of each of the light emitting elements LE. The pixel defining layer PDL may cover edges of the first electrode AND of each of the light emitting elements LE. The pixel defining layer PDL may define first through third emission areas EA1 through EA3.

The first emission area EA1 may be defined as an area in the first subpixel SP1 where the first electrode AND, the light emitting stack IL, and the second electrode CAT are sequentially stacked to emit light. The second emission area EA2 may be defined as an area in the second subpixel SP2 where the first electrode AND, the light emitting stack IL, and the second electrode CAT are sequentially stacked to emit light. The third emission area EA3 may be defined as an area in the third subpixel SP3 where the first electrode AND, the light emitting stack IL, and the second electrode CAT are sequentially stacked to emit light.

The pixel defining layer PDL may include first through third pixel defining layers PDL1 through PDL3. The first pixel defining layer PDL1 may be disposed on the edges of the first electrode AND of each of the light emitting elements LE. The second pixel defining layer PDL2 may be disposed on the first pixel defining layer PDL1. The third pixel defining layer PDL3 may be disposed on the second pixel defining layer PDL2. Each of the first pixel defining layer PDL1, the second pixel defining layer PDL2, and the third pixel defining layer PDL3 may be a silicon oxide (SiOₓ)-based inorganic layer, but embodiments of the disclosure are not limited thereto. A thickness of the first pixel defining layer PDL1, a thickness of the second pixel defining layer PDL2, and a thickness of the third pixel defining layer PDL3 may each be about 500 Å in the third direction DR3.

In case that the first pixel defining layer PDL1, the second pixel defining layer PDL2, and the third pixel defining layer PDL3 are formed as a single pixel defining layer, a height of the single pixel defining layer may increase, and a first encapsulating inorganic layer TFE1 may be damaged due to step coverage. The step coverage may refer to the ratio of the extent to which a thin film is applied on an inclined portion to the extent to which the thin film is applied on a flat portion. The lower the step coverage, the higher the probability that the thin film will break in the inclined portion.

Therefore, in order to prevent the first encapsulating inorganic layer TFE1 from being broken due to the step coverage, the first pixel defining layer PDL1, the second pixel defining layer PDL2, and the third pixel defining layer PDL3 may have a cross-sectional structure having steps. For example, a width of the first pixel defining layer PDL1 may be greater than a width of the second pixel defining layer PDL2 and a width of the third pixel defining layer PDL3, and the width of the second pixel defining layer PDL2 may be greater than the width of the third pixel defining layer PDL3. The width of the first pixel defining layer PDL1 may refer to a horizontal length of the first pixel defining layer PDL1 defined by the first direction DR1 and the second direction DR2.

Each of the trenches TRC may penetrate the first pixel defining layer PDL1, the second pixel defining layer PDL2, and the third pixel defining layer PDL3. Each of the trenches TRC may further penetrate the eleventh insulating layer INS11. A portion of the tenth insulating layer INS10 may have a recessed shape in each of the trenches TRC.

At least one trench TRC may be disposed between neighboring subpixels SP1 through SP3. Although two trenches TRC are disposed between the neighboring subpixels SP1 through SP3 in FIG. 7, embodiments of the disclosure are not limited thereto.

The light emitting stack IL may include multiple intermediate layers. FIG. 7 illustrates that the light emitting stack IL has a three-tandem structure including a first stack layer IL1, a second stack layer IL2, and a third stack layer IL3. However, embodiments of the disclosure are not limited thereto. In another embodiment, the light emitting stack IL may have a two-tandem structure including two intermediate layers.

In the three-tandem structure, the light emitting stack IL may have a tandem structure including multiple stack layers IL1 through IL3 that emit different lights. For example, the light emitting stack IL may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light emitting layer emitting light of the first color, and a first electron transport layer are sequentially stacked. The second stack layer IL2 may have a structure in which a second hole transport layer, a second organic light emitting layer emitting light of the third color, and a second electron transport layer are sequentially stacked. The third stack layer IL3 may have a structure in which a third hole transport layer, a third organic light emitting layer emitting light of the second color, and a third electron transport layer are sequentially stacked.

A first charge generation layer may be disposed between the first stack layer IL1 and the second stack layer IL2 to supply charges to the second stack layer IL2 and electrons to the first stack layer IL1. The first charge generation layer may include an N-type charge generation layer that supplies electrons to the first stack layer IL1 and a P-type charge generation layer that supplies holes to the second stack layer IL2. The N-type charge generation layer may include a dopant of a metallic material.

A second charge generation layer may be disposed between the second stack layer IL2 and the third stack layer IL3 to supply charges to the third stack layer IL3 and electrons to the second stack layer IL2. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining layer PDL and may be disposed on a bottom surface of each of the trenches TRC. Due to the trenches TRC, the first stack layer IL1 may be broken between neighboring subpixels SP1 through SP3. The second stack layer IL2 may be disposed on the first stack layer IL1. Due to the trenches TRC, the second stack layer IL2 may be broken between the neighboring subpixels SP1 through SP3. A void or an empty space ESS may be disposed between the first stack layer IL1 and the second stack layer IL2. The third stack layer IL3 may be disposed on the second stack layer IL2. The third stack layer IL3 may not be broken by the trenches TRC and may cover the second stack layer IL2 in each of the trenches TRC. For example, in the three-tandem structure, each of the trenches TRC may be a structure for breaking the first and second stack layers IL1 and IL2, the first charge generation layer, and the second charge generation layer of the display element layer EML between the neighboring subpixels SP1 through SP3. In the two-tandem structure, each of the trenches TRC may be a structure for breaking a charge generation layer disposed between a lower intermediate layer and an upper intermediate layer and breaking the lower intermediate layer.

In order to stably break the first and second stack layers IL1 and IL2 of the display element layer EML between the neighboring subpixels SP1 through SP3, a height of each of the trenches TRC may be greater than a height of the pixel defining layer PDL in the third direction DR3. The height of each of the trenches TRC may refer to a length of each of the trenches TRC in the third direction DR3. The height of the pixel defining layer PDL may refer to a length of the pixel defining layer PDL in the third direction DR3. In order to break the first through third stack layers IL1 through IL3 of the display element layer EML between the neighboring subpixels SP1 through SP3, another structure may exist instead of the trenches TRC. For example, instead of the trenches TRC, reverse tapered barrier ribs may be disposed on the pixel defining layer PDL.

The number of stack layers IL1 through IL3 emitting different lights is not limited to the embodiment illustrated in FIG. 7. For example, the light emitting stack IL may include two intermediate layers. One of the two intermediate layers may be substantially the same as the first stack layer IL1, and another one of the two intermediate layers may include a second hole transport layer, a second organic light emitting layer, a third organic light emitting layer, and a second electron transport layer. A charge generation layer may be disposed between the two intermediate layers to supply electrons to one of the two intermediate layers and to supply charges to the another one of the two intermediate layers.

FIG. 7 illustrates that the first through third stack layers IL1 through IL3 are disposed in all of the first emission area EA1, the second emission area EA2, and the third emission area EA3. However, embodiments of the disclosure are not limited thereto. For example, the first stack layer IL1 may be disposed in the first emission area EA1 and may not be disposed in the second emission area EA2 and the third emission area EA3. The second stack layer IL2 may be disposed in the second emission area EA2 and may not be disposed in the first emission area EA1 and the third emission area EA3. The third stack layer IL3 may be disposed in the third emission area EA3 and may not be disposed in the first emission area EA1 and the second emission area EA2. First through third color filters CF1 through CF3 of the optical layer OPL may be omitted.

The second electrode CAT may be disposed on the third stack layer IL3. The second electrode CAT may be disposed on the third stack layer IL3 in each of the trenches TRC. The second electrode CAT may be made of a transparent conductive material (TCO) that can transmit light, such as indium tin oxide (ITO) or indium zinc oxide (IZO), or a semi-transmissive conductive material such as magnesium (Mg), silver (Ag) or an alloy of Mg and Ag. In case that the second electrode CAT is made of a semi-transmissive conductive material, the light output efficiency of each of the first through third subpixels SP1 through SP3 may be increased by a microcavity.

The encapsulation layer TFE may be disposed on the display element layer EML. The encapsulation layer TFE may include one or more inorganic layers TFE1 and TFE2 to prevent the penetration of oxygen or moisture into the display element layer EML. For example, the encapsulation layer TFE may include the first encapsulating inorganic layer TFE1 and a second encapsulating inorganic layer TFE2.

The first encapsulating inorganic layer TFE1 may be disposed on the second electrode CAT. The first encapsulating inorganic layer TFE1 may be a multilayer in which one or more inorganic layers selected from silicon nitride (SiNₓ), silicon oxynitride (SiON), and silicon oxide (SiOₓ) are alternately stacked each other. The first encapsulating inorganic layer TFE1 may be formed by a chemical vapor deposition (CVD) process.

The second encapsulating inorganic layer TFE2 may be disposed on the first encapsulating inorganic layer TFE1. The second encapsulating inorganic layer TFE2 may be a titanium oxide (TiOx) or aluminum oxide (AlOₓ) layer, but embodiments of the disclosure are not limited thereto. The second encapsulating inorganic layer TFE2 may be formed by an atomic layer deposition (ALD) process. A thickness of the second encapsulating inorganic layer TFE2 may be smaller than a thickness of the first encapsulating inorganic layer TFE1 in the third direction DR3.

An organic layer APL may be a layer for increasing the interfacial adhesion between the encapsulation layer TFE and the optical layer OPL. The organic layer APL may include an acryl resin, an epoxy resin, a phenolic resin, a polyamide resin, or a polyimide resin.

The optical layer OPL may include multiple color filters CF1 through CF3, multiple lenses LNS, and a filling layer FIL. The color filters CF1 through CF3 may include the first through third color filters CF1 through CF3. The first through third color filters CF1 through CF3 may be disposed on the organic layer APL.

The first color filter CF1 may overlap the first emission area EA1 of the first subpixel SP1 in the third direction DR3. The first color filter CF1 may transmit light of the first color, for example, light in the blue wavelength band. The blue wavelength band may be in a range of about 370 nm to about 460 nm. Therefore, the first color filter CF1 may transmit the light of the first color among the light emitted from the first emission area EA1.

The second color filter CF2 may overlap the second emission area EA2 of the second subpixel SP2 in the third direction DR3. The second color filter CF2 may transmit light of the second color, for example, light in the green wavelength band. The green wavelength band may be in a range of about 480 nm to about 560 nm. Therefore, the second color filter CF2 can transmit the light of the second color among the light emitted from the second emission area EA2.

The third color filter CF3 may overlap the third emission area EA3 of the third subpixel SP3 in the third direction DR3. The third color filter CF3 may transmit light of the third color, for example, light in the red wavelength band. The red wavelength band may be in a range of about 600 nm to about 750 nm. Therefore, the third color filter CF3 can transmit the light of the third color among the light emitted from the third emission area EA3.

The lenses LNS may be disposed on the first color filter CF1, the second color filter CF2, and the third color filter CF3, respectively. Each of the lenses LNS may be a structure for increasing the proportion of light directed to the front of the display device 10. Each of the lenses LNS may have an upwardly convex cross-sectional shape.

The filling layer FIL may be disposed on the lenses LNS. The filling layer FIL may have a refractive index so that light can travel in the third direction DR3 at an interface between the lenses LNS and the filling layer FIL. The filling layer FIL may be a planarization layer. The filling layer FIL may include an acryl resin, an epoxy resin, a phenolic resin, a polyamide resin, or a polyimide resin.

The cover layer CVL may be disposed on the filling layer FIL. The cover layer CVL may be a glass substrate or a polymer resin such as resin. In case that the cover layer CVL is a glass substrate, the cover layer CVL may be attached onto the filling layer FIL, and the filling layer FIL may serve to bond the cover layer CVL. In case that the cover layer CVL is a glass substrate, the cover layer CVL may serve as an encapsulation substrate. In case that the cover layer CVL is a polymer resin such as resin, the cover layer CVL may be directly applied on the filling layer FIL.

The polarizer POL may be disposed on a surface of the cover layer CVL. The polarizer POL may be a structure for preventing visibility reduction due to the reflection of external light. The polarizer POL may include a linear polarizer and a phase retardation film. For example, the phase retardation film may be a quarter-wave plate (λ/4 plate), but embodiments of the disclosure are not limited thereto. If visibility due to the reflection of external light is sufficiently improved by the first through third color filters CF1 through CF3, the polarizer POL may be omitted.

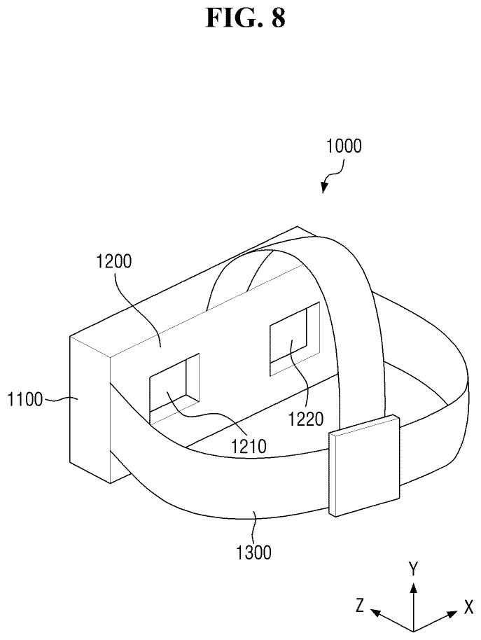

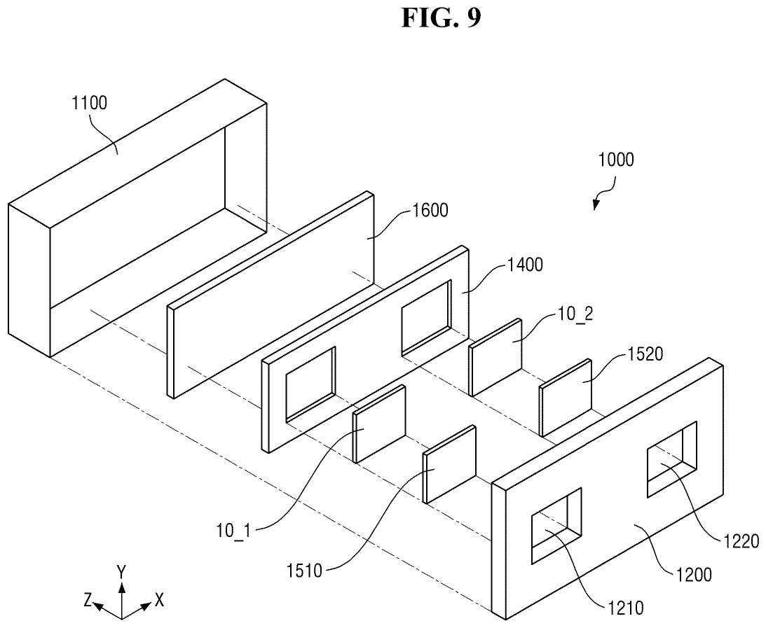

FIG. 8 is a perspective view of a head mounted display device 1000 according to an embodiment. FIG. 9 is an exploded perspective view of the head mounted display device 1000 of FIG. 8 according to an embodiment.

Referring to FIGS. 8 and 9, the head mounted display device 1000 according to an embodiment may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 101 may provide an image to a user's left eye, and the second display device 102 may provide an image to the user's right eye. Each of the first display device 10_1 and the second display device 102 may be substantially the same as the display device 10 described with reference to FIGS. 1 and 2. Therefore, a description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and may be disposed between the second display device 10_2 and the control circuit board 1600. The middle frame 1400 may support and fix the first display device 10_1, the second display device 102, and the control circuit board 1600.

The control circuit board 1600 may be disposed between the middle frame 1400 and the display device housing 1100. The control circuit board 1600 may be connected to the first display device 10_1 and the second display device 10_2 through a connector. The control circuit board 1600 may convert an image source received from the outside into digital video data DATA and transmit the digital video data DATA to the first display device 10_1 and the second display device 10_2 through the connector.

The control circuit board 1600 may transmit the digital video data DATA corresponding to a left image optimized for a user's left eye to the first display device 10_1 and transmit the digital video data DATA corresponding to a right image optimized for the user's right eye to the second display device 10_2. In another embodiment, the control circuit board 1600 may transmit a same digital video data DATA to the first display device 10_1 and the second display device 10_2.

The display device housing 1100 may house the first display device 10_1, the second display device 102, the middle frame 1400, the first optical member 1510, the second optical member 1520, and the control circuit board 1600. The housing cover 1200 may cover an open surface of the display device housing 1100. The housing cover 1200 may include the first eyepiece 1210 on which a user's left eye is placed and the second eyepiece 1220 on which the user's right eye is placed. Although FIGS. 8 and 9 illustrate that the first eyepiece 1210 and the second eyepiece 1220 are disposed separately, embodiments of the disclosure are not limited thereto. In another embodiment, the first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, a user may view an image of the first display device 10_1, which is enlarged as a virtual image by the first optical member 1510, through the first eyepiece 1210 and may view an image of the second display device 10_2, which is enlarged as a virtual image by the second optical member 1520, through the second eyepiece 1220.

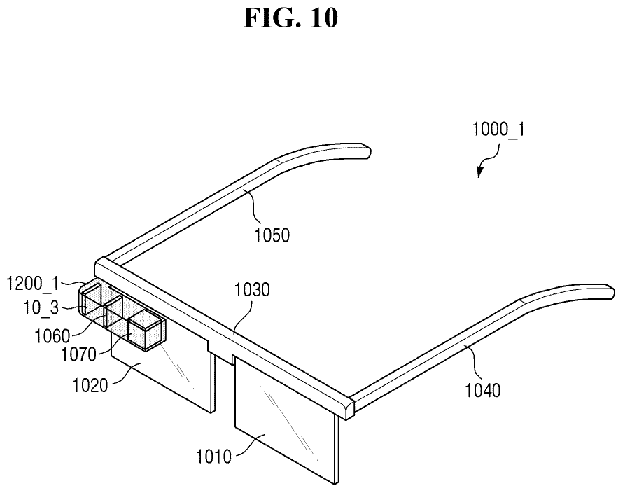

The head mounted band 1300 may fix the display device housing 1100 to a user's head so that the first eyepiece 1210 and the second eyepiece 1220 of the housing cover 1200 may be kept placed on the user's left and right eyes, respectively. In case that the display device housing 1200 is implemented to be lightweight and small, the head mounted display device 1000 may include an eyeglass frame as illustrated in FIG. 10 instead of the head mounted band 1300.

The head mounted display device 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a perspective view of a head mounted display device 1000_1 according to an embodiment.

Referring to FIG. 10, the head mounted display device 1000_1 according to an embodiment may be a display device in the form of glasses in which a display device housing 1200_1 is implemented to be lightweight and small. The head mounted display device 1000_1 according to an embodiment may include a display device 10_3, a left lens 1010, a right lens 1020, a support frame 1030, eyeglass frame legs 1040 and 1050, an optical member 1600, an optical path conversion member 1070, and the display device housing 1200_1.

The display device housing 1200_1 may house the display device 10_3, the optical member 1060, and the optical path conversion member 1070. An image displayed on the display device 10_3 may be enlarged by the optical member 1600, may have its optical path converted by the optical path conversion member 1700, and may be provided to a user's right eye through the right lens 1020. Accordingly, the user may view, through the right eye, an augmented reality image into which a virtual image displayed on the display device 10_3 and a real image viewed through the right lens 1020 are combined.

Although FIG. 10 illustrates that the display device housing 12001 is disposed at a right end of the support frame 1030, embodiments of the disclosure are not limited thereto. In another embodiment, the display device housing 1200_1 may be disposed at a left end of the support frame 1030, and an image of the display device 103 may be provided to a user's left eye. In another embodiment, the display device housing 1200_1 may be disposed at both the left and right ends of the support frame 1030, and the user may view an image displayed on the display device 10_3 through both the left and right eyes.

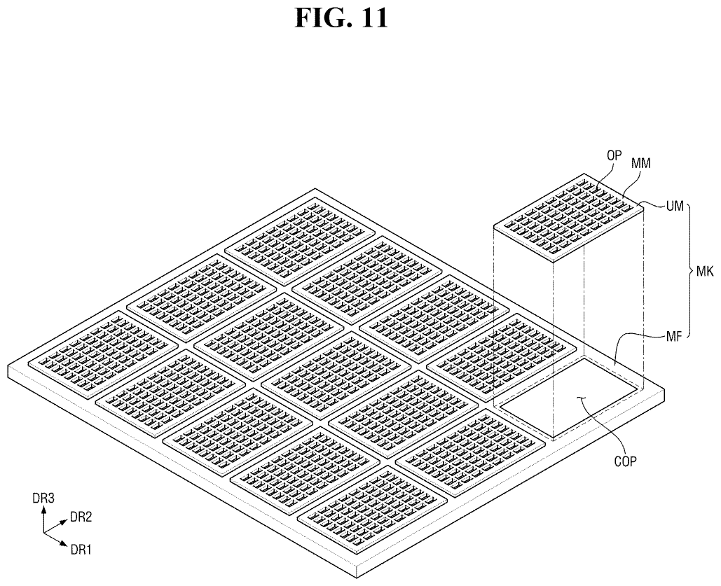

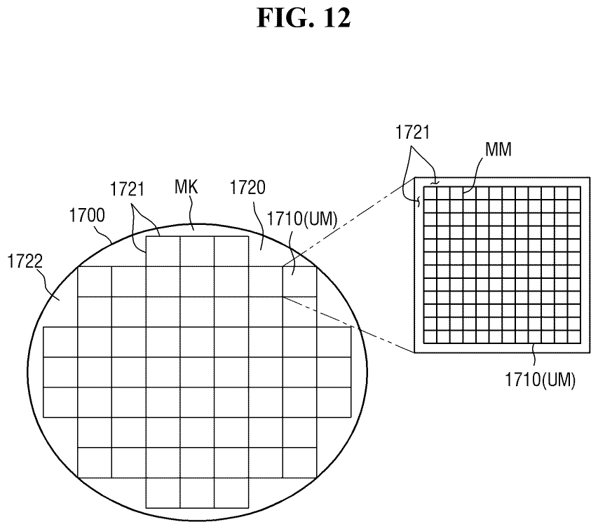

FIG. 11 is a perspective view of a mask MK according to an embodiment. FIG. 12 is a schematic plan view of the mask MK according to the embodiment. FIG. 11 is a perspective view illustrating a state in which one unit mask UM is separated from multiple unit masks. The mask MK according to the embodiment illustrated in FIGS. 11 and 12 may be used in a process of depositing at least a portion of the light emitting stack IL described with reference to FIG. 7. For example, the light emitting stack IL may be configured to emit light of different colors in the subpixels SP1 through SP3.

Referring to FIGS. 11 and 12, the mask MK according to an embodiment may be a shadow mask in which mask membranes MM are disposed on a silicon substrate 1700. The mask MK according to the embodiment may be referred to as a “silicon mask.”

According to an embodiment, the mask MK may include the silicon substrate 1700, and the mask membranes MM may be disposed on the silicon substrate 1700. The mask membranes MM may be respectively disposed in cell areas 1710 arranged in a matrix form, and each cell area 1710 may be surrounded by a mask rib area 1721. The mask rib area 1721 may support the mask membranes MM.

A mask membrane MM may be a part of a unit mask UM disposed in each of the cell areas 1710.

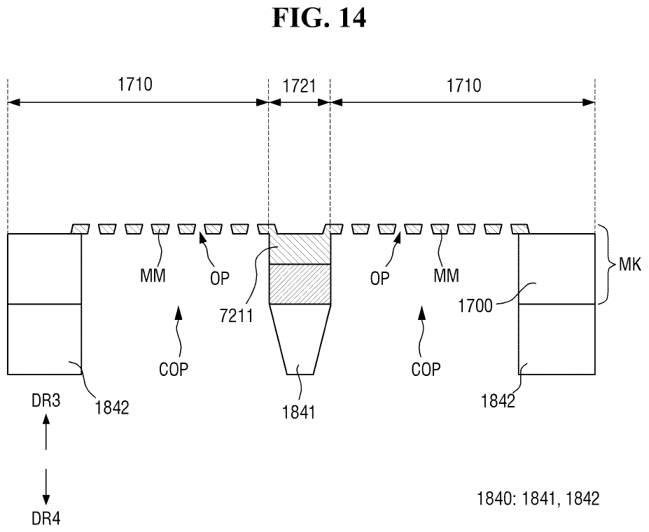

The silicon substrate 1700 may include multiple cell areas 1710 and a mask frame area 1720 excluding the cell areas 1710. The mask frame area 1720 may include the mask rib area 1721 surrounding each cell area 1710 and an outer frame area 1722 disposed at an outermost periphery of the silicon substrate 1700. A mask frame MF may be disposed in the mask frame area 1720. The mask frame MF may include mask ribs 7211 (see FIG. 14) surrounding the cell areas 1710.

The mask rib area 1721 may be an area that separates the cell areas 1710. For example, the cell areas 1710 may be arranged in a matrix form, and the mask ribs 7211 (see FIG. 14) disposed in the mask rib area 1721 may surround the outside of the mask membrane MM disposed in each of the cell areas 1710.

A cell opening COP and a unit mask UM that masks at least a portion of the cell opening COP may be disposed in each of the cell areas 1710 of the silicon substrate 1700.

Multiple cell openings COP may penetrate the mask frame MF in the thickness direction (e.g., the third direction DR3) of the mask MK. The cell openings COP may be formed by partially etching the silicon substrate 1700 from a back side.

Each unit mask UM may include a mask membrane MM, and the mask membrane MM may include mask openings OP.

The mask openings OP of each mask membrane MM may be referred to as “holes” or “mask holes”. The mask openings OP may penetrate the unit masks UM in the thickness direction (e.g., the third direction DR3) of the mask MK.

A unit mask UM may be used in a deposition process of a display panel 100. In the disclosure, the term “unit mask UM” may be replaced with a term such as “mask unit UM”.

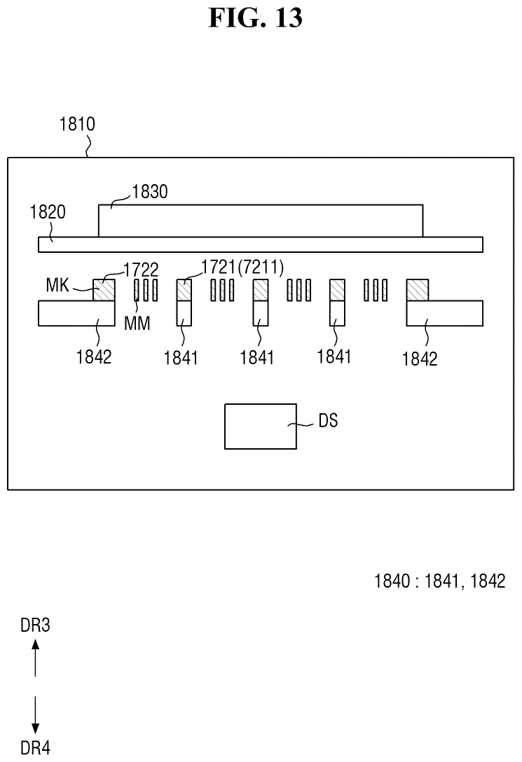

FIG. 13 is a schematic cross-sectional view illustrating the configuration of deposition equipment according to an embodiment.

Referring to FIG. 13, the deposition equipment according to an embodiment may include a chamber 1810, a deposition source DS disposed inside the chamber 1810, a mask MK disposed between a first substrate 1820 and the deposition source DS inside the chamber 1810, and a mask support 1840 disposed between the deposition source DS and the mask MK to support at least a portion of the mask MK.

According to an embodiment, the mask MK may include a second substrate 1700 which includes multiple cell areas 1710 and a mask frame area 1720 excluding the cell areas 1710 and a mask membrane MM which is disposed in each of the cell areas 1710.

The first substrate 1820 illustrated in FIG. 13 may be the display panel 100 described with reference to FIGS. 1 through 10. Therefore, a description of the first substrate 1820 will be replaced with the description of the display panel 100 with reference to FIGS. 1 through 10.

The second substrate 1700 illustrated in FIG. 13 may be the silicon substrate 1700 described with reference to FIGS. 11 and 12. Therefore, a description of the second substrate 1700 will be replaced with the description of the silicon substrate 1700 with reference to FIGS. 11 and 12.

The mask support 1840 may be disposed under the mask MK to support and fix the mask MK. For example, the mask support 1840 may include an electrostatic chuck. According to an embodiment, the mask support 1840 may include a first support area 1841 supporting a mask rib area 1721 and a second support area 1842 supporting an outer frame area 1722.

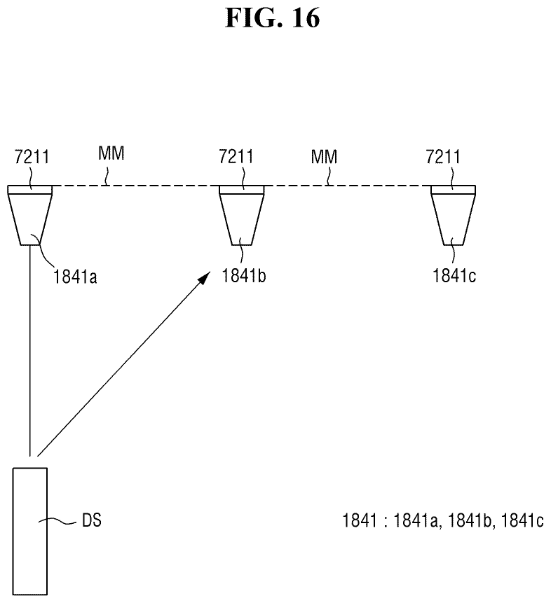

According to an embodiment, multiple support ribs 1841a, 1841b and 1841c may be disposed in the first support area 1841 of the mask support 1840, as will be described below with reference to FIGS. 16 through 23.

According to an embodiment, the electrostatic chuck of the mask support 1840 may be formed integrally with the support ribs 1841a, 1841b and 1841c.

According to an embodiment, the electrostatic chuck of the mask support 1840 may be provided separately from the support ribs 1841a, 1841b and 1841c and may be coupled to some of the support ribs 1841a, 1841b and 1841c.

According to an embodiment, the mask support 1840 may include invar, stainless steel, or ceramic.

Reference numeral 1830 in FIG. 13 may indicate a fixing member for fixing the first substrate 1820 and may include, for example, an electrostatic chuck.

FIG. 14 is a schematic cross-sectional view of a mask MK according to an embodiment.

Referring to FIG. 14, a silicon substrate 1700 of the mask MK may be divided into multiple cell areas 1710 and a mask frame area 1720 excluding the cell areas 1710. The mask frame area 1720 may include a mask rib area 1721 surrounding the outside of each of the cell areas 1710.

Mask membranes MM may be disposed on the silicon substrate 1700 and may be exposed in a backward direction DR4 through cell openings COP of the silicon substrate 1700. The backward direction DR4 may refer to a direction facing a deposition source DS (see FIG. 13).

A cross section of each mask membrane MM may have a reverse tapered shape which decreases in width from a forward direction DR3 of the silicon substrate 1700 toward the backward direction DR4 of the silicon substrate 1700.

Each of the mask membranes MM may include mask shadows made of a metal layer or an inorganic layer and a hole OP disposed between neighboring mask shadows.

A mask rib 7211 surrounding the outside of the mask membrane MM disposed in each cell area 1710 may be disposed in the mask rib area 1721. The mask rib 7211 and the mask membranes MM may be made of a same material. For example, the mask rib 7211 may be made of a metal layer, but the disclosure is not limited thereto. For example, although not illustrated, the mask rib 7211 may be a portion left after a portion of the silicon substrate 1700 is patterned.

As illustrated, a mask support 1840 may be disposed under the mask MK and support the mask MK. The mask support 1840 may include a first support area 1841 supporting the mask rib area 1721 and a second support area 1842 supporting an outer frame area 1722.

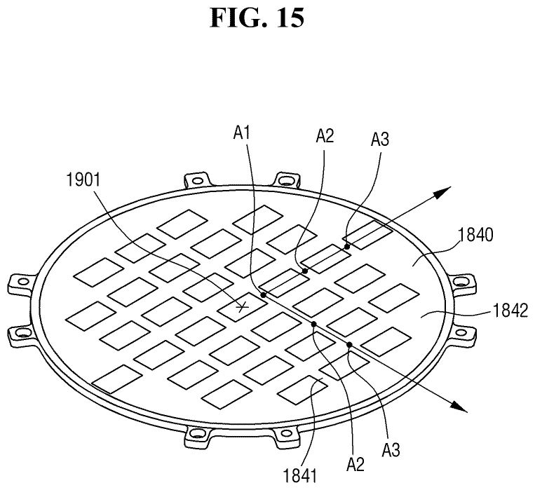

FIG. 15 is a perspective view of a mask support 1840 according to an embodiment. FIG. 16 schematically illustrates multiple support ribs 1841a, 1841b and 1841c of the mask support 1840 according to the embodiment.

Referring to FIGS. 15 and 16, the mask support 1840 may include multiple support ribs 1841a, 1841b and 1841c, each supporting a mask rib area 1721 and having a cross-sectional structure of a taper angle. For example, the support ribs 1841a, 1841b and 1841c may include a first support rib 1841a, a second support rib 1841b, and a third support rib 1841c according to the distance from a center 1901 of a mask MK. However, the disclosure is not limited to the embodiment that the mask support 1840 includes the first support rib 1841a, the second support rib 1841b, and the third support rib 1841c.

According to an embodiment, the first support rib 1841a may form a first deposition incidence angle with a deposition source DS and support a first mask rib area A1 spaced apart from the center 1901 of the mask MK by a first distance.

According to an embodiment, the second support rib 1841b may form a second deposition incidence angle, which is greater than the first deposition incidence angle, with the deposition source DS and support a second mask rib area A2 spaced apart from the center 1901 of the mask MK by a second distance. The second distance may be greater than the first distance.

According to an embodiment, the third support rib 1841c may form a third deposition incidence angle, which is greater than the second deposition incidence angle, with the deposition source DS and support a third mask rib area A3 spaced apart from the center 1901 of the mask MK by a third distance. The third distance may be greater than the second distance.

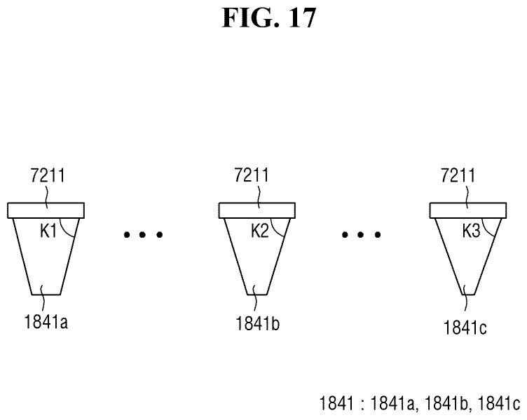

According to an embodiment, a taper angle K1, K2 or K3 (see FIG. 17) of each of the support ribs 1841a, 1841b and 1841c may be smaller than or equal to a deposition incidence angle formed by the deposition source DS and the support rib 1841a, 1841b or 1841c.

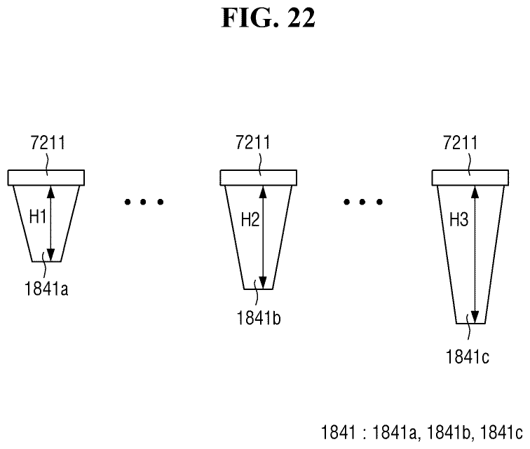

According to an embodiment, the taper angles K1, K2 and K3 (see FIG. 17) of the support ribs 1841a, 1841b and 1841c may be different from each other. Shapes of the support ribs 1841a, 1841b and 1841c may be different from each other. Heights H1, H2 and H3 (see FIG. 22) of the support ribs 1841a, 1841b and 1841c may be different from each other. The shapes of the support ribs 1841a, 1841b and 1841c of the disclosure will be described in detail with reference to FIGS. 17 through 23.

FIGS. 17 through 23 are schematic cross-sectional views illustrating structures of first through third support ribs 1841a, 1841b and 1841c according to embodiments.

FIG. 17 illustrates an embodiment in which taper angles K1, K2 and K3 of the support ribs 1841a, 1841b and 1841c decrease toward the periphery of a mask support 1840.

Referring to FIG. 17, the cross-sectional structure of a first support rib 1841a may have a first taper angle K1 which is smaller than or equal to a first deposition incidence angle, the cross-sectional structure of a second support rib 1841b may have a second taper angle K2 which is smaller than or equal to a second deposition incidence angle, and the cross-sectional structure of a third support rib 1841c may have a third taper angle K3 which is smaller than or equal to a third deposition incidence angle.

According to an embodiment, the first taper angle K1 may be greater than or equal to the second taper angle K2, and the second taper angle K2 may be greater than or equal to the third taper angle K3.

As described above, the taper angles K1, K2 and K3 of the support ribs 1841a, 1841b and 1841c included in the mask support 1840 according to an embodiment may decrease toward the periphery of the mask support 1840.

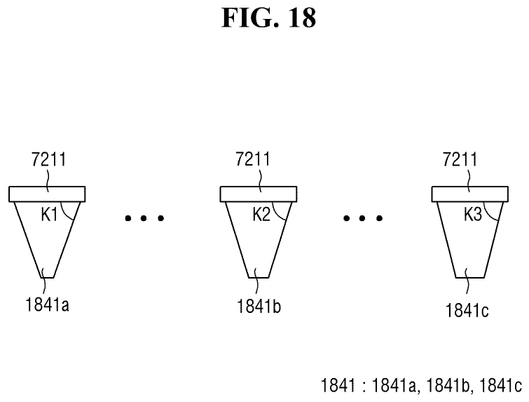

FIG. 18 illustrates an embodiment in which taper angles K1, K2 and K3 of multiple support ribs 1841a, 1841b and 1841c increase toward the periphery of a mask support 1840.

The embodiment of FIG. 18 may be different from the embodiment of FIG. 17 in that a first taper angle K1 is smaller than or equal to a second taper angle K2, and the second taper angle K2 is smaller than or equal to a third taper angle K3.

As described above, the taper angles K1, K2 and K3 of the support ribs 1841a, 1841b and 1841c included in the mask support 1840 according to an embodiment may increase toward the periphery of the mask support 1840.

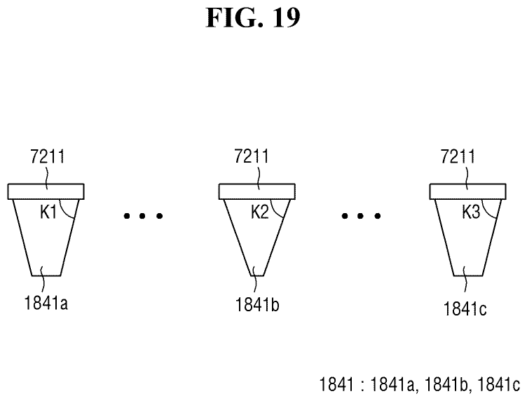

FIG. 19 illustrates an embodiment in which taper angles K1, K2 and K3 of multiple support ribs 1841a, 1841b and 1841c decrease and increase toward the periphery of a mask support 1840.

The embodiment of FIG. 19 may be different from the embodiment of FIG. 17 in that a first taper angle K1 is equal to a third taper angle K3, and a second taper angle K2 is smaller than the first taper angle K1.

As described above, the taper angles K1, K2 and K3 of the support ribs 1841a, 1841b and 1841c included in the mask support 1840 according to the embodiment may decrease and increase toward the periphery of the mask support 1840.

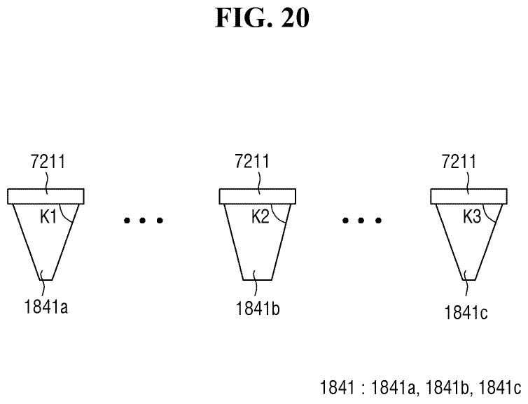

FIG. 20 illustrates an embodiment in which taper angles K1, K2 and K3 of multiple support ribs 1841a, 1841b and 1841c increase and decrease toward the periphery of a mask support 1840.

The embodiment of FIG. 20 may be different from the embodiment of FIG. 17 in that a first taper angle K1 is equal to a third taper angle K3 and smaller than a second taper angle K2.

As described above, the taper angles K1, K2 and K3 of the support ribs 1841a, 1841b and 1841c included in the mask support 1840 according to the embodiment may increase and decrease toward the periphery of the mask support 1840.

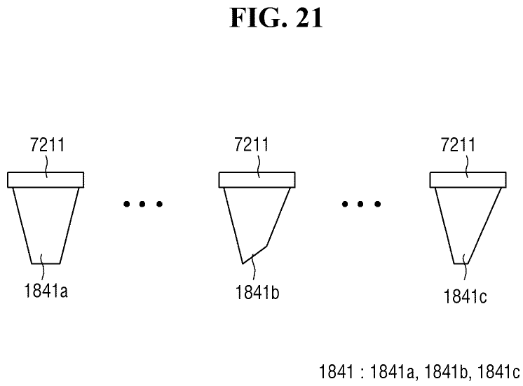

FIG. 21 illustrates an embodiment in which one of multiple support ribs 1841a, 1841b and 1841c includes an asymmetrical cross-sectional structure.

The embodiment of FIG. 21 may be different from the embodiments of FIGS. 17 through 20 in that a cross section of one of first through third support ribs 1841c has an asymmetrical structure. For example, although the cross section of each of the first through third support ribs 1841a, 1841b and 1841c has a symmetrical structure in the embodiments of FIGS. 17 through 20, the disclosure is not limited thereto.

FIG. 22 illustrates an embodiment in which heights H1, H2 and H3 of multiple support ribs 1841a, 1841b and 1841c increase toward the periphery of a mask support 1840.

Referring to FIG. 22, heights H1, H2 and H3 of first through third support ribs 1841a, 1841b and 1841c may be different from each other. For example, the first support rib 1841a may have a first height H1, the second support rib 1841b may have a second height H2 greater than the first height H1, and the third support rib 1841c may have a third height H3 greater than the second height H2.

As described above, the heights H1, H2 and H3 of the support ribs 1841a, 1841b and 1841c included in the mask support 1840 according to the embodiment may increase toward the periphery of the mask support 1840.

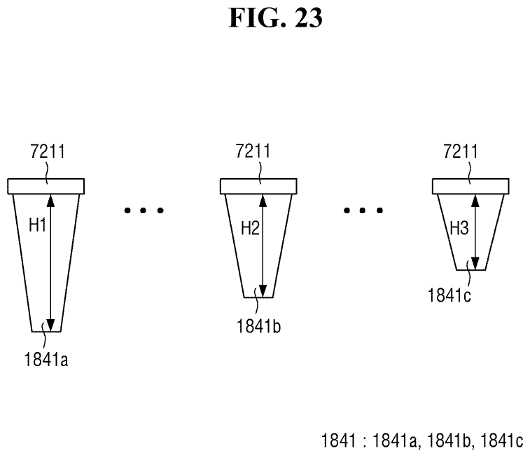

FIG. 23 illustrates an embodiment in which heights H1, H2 and H3 of multiple support ribs 1841a, 1841b and 1841c decrease toward the periphery of a mask support 1840.

The embodiment of FIG. 23 may be different from the embodiment of FIG. 22 in that a first support rib 1841a has a first height H1, a second support rib 1841b has a second height H2 smaller than the first height H1, and a third support rib 1841c has a third height H3 smaller than the second height H2.

As described above, the heights H1, H2 and H3 of the support ribs 1841a, 1841b and 1841c included in the mask support 1840 according to the embodiment may decrease toward the periphery of the mask support 1840.

In deposition equipment according to an embodiment, a mask support that supports a mask may include multiple support ribs, each having a taper angle smaller than or equal to a deposition incidence angle, and taper angles of the support ribs may be designed to be different from each other. Therefore, shadow defects may be minimized.

Since the support ribs have designated taper angles, a thickness of the mask support may be increased, and the mask support may support the mask more stably.

With deposition equipment according to embodiments, it may be possible to readily manufacture a display panel with a high resolution of 3500 pixels per inch (PPI) or higher.

A mask support that supports a mask may include multiple support ribs, each having a taper angle smaller than or equal to a deposition incidence angle, and taper angles of the support ribs may be designed to be different from each other. Therefore, shadow defects may be minimized.

Since the support ribs have designated taper angles, a thickness of the mask support may be increased, and the mask support may support the mask more stably.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. Deposition equipment comprising:
a chamber;
a deposition source disposed inside the chamber;
a mask disposed between a first substrate and the deposition source inside the chamber; and
a mask support disposed between the deposition source and the mask and supporting at least a portion of the mask, wherein
the mask comprises a plurality of cell areas and a mask frame area excluding the plurality of cell areas,
the mask frame area comprises a mask rib area separating the plurality of cell areas and an outer frame area disposed at an outermost periphery of the mask,
the mask support comprises a plurality of support ribs, each supporting the mask rib area and having a cross-sectional structure having a taper angle, and
the taper angle of each of the plurality of support ribs are different from each other.

2. The deposition equipment of claim 1, wherein the mask support further comprises an electrostatic chuck which supports the outer frame area.

3. The deposition equipment of claim 2, wherein the electrostatic chuck of the mask support is integrally formed with the plurality of support ribs.

4. The deposition equipment of claim 2, wherein the electrostatic chuck of the mask support is provided separately from the plurality of support ribs and coupled to some of the plurality of support ribs.

5. The deposition equipment of claim 1, wherein a material of the mask support comprises invar.

6. The deposition equipment of claim 1, wherein a material of the mask support comprises stainless steel.

7. The deposition equipment of claim 1, wherein the taper angle of each of the plurality of support ribs is smaller than or equal to a deposition incidence angle formed by the deposition source and each of the plurality of support ribs.

8. The deposition equipment of claim 7, wherein the plurality of support ribs comprise:
a first support rib which forms a first deposition incidence angle with the deposition source and supports a first mask rib area spaced apart from a center of the mask by a first distance;
a second support rib which forms a second deposition incidence angle greater than the first deposition incidence angle with the deposition source and supports a second mask rib area spaced apart from the center of the mask by a second distance; and
a third support rib which forms a third deposition incidence angle greater than the second deposition incidence angle with the deposition source and supports a third mask rib area spaced apart from the center of the mask by a third distance.

9. The deposition equipment of claim 8, wherein
a cross-sectional structure of the first support rib has a first taper angle smaller than or equal to the first deposition incidence angle,
a cross-sectional structure of the second support rib has a second taper angle smaller than or equal to the second deposition incidence angle, and
a cross-sectional structure of the third support rib has a third taper angle smaller than or equal to the third deposition incidence angle.

10. The deposition equipment of claim 9, wherein
the first taper angle is greater than or equal to the second taper angle, and
the second taper angle is greater than or equal to the third taper angle.

11. The deposition equipment of claim 9, wherein
the first taper angle is smaller than or equal to the second taper angle, and
the second taper angle is smaller than or equal to the third taper angle.

12. The deposition equipment of claim 9, wherein
the first taper angle is equal to the third taper angle, and
the second taper angle is smaller than the first taper angle.

13. The deposition equipment of claim 9, wherein the first taper angle is equal to the third taper angle and smaller than the second taper angle.

14. The deposition equipment of claim 8, wherein each of the first through third support ribs has a symmetrical structure in a cross-sectional view.

15. The deposition equipment of claim 8, wherein each of the first through third support ribs has an asymmetrical structure in a cross-sectional view.

16. The deposition equipment of claim 8, wherein heights of the first through third support ribs are different from each other.

17. The deposition equipment of claim 16, wherein
the first support rib has a first height,
the second support rib has a second height greater than the first height, and
the third support rib has a third height greater than the second height.

18. The deposition equipment of claim 16, wherein
the first support rib has a first height,
the second support rib has a second height smaller than the first height, and
the third support rib has a third height smaller than the second height.

19. The deposition equipment of claim 1, wherein the mask further comprises a mask membrane comprising an inorganic layer.

20. The deposition equipment of claim 1, wherein the mask further comprises a mask membrane comprising a metal layer.
